(19) United States
(12) Patent Application Publication
(10) Pub. No.: US 2026/0256016 A1
(43) Pub. Date: Aug. 27, 2026

(54) SEMICONDUCTOR DEVICE INCLUDING CELL STACK AND PERIPHERAL CIRCUIT STACK

(71) Applicant: Samsung Electronics Co., Ltd., Suwon-si (KR)

(72) Inventor: Jeonil Lee, Suwon-si (KR)

(73) Assignee: Samsung Electronics Co., Ltd., Suwon-si (KR)

(21) Appl. No.: 19/540,358

(22) Filed: Feb. 13, 2026

(30) Foreign Application Priority Data
Feb. 25, 2025 (KR) 10-2025-0024515

(51) Int. Cl. H10W 74/10; H10W 20/20; H10W 90/00

(52) U.S. Cl. CPC H10W 74/117; H10W 20/20; H10W 90/724

(57) ABSTRACT

A semiconductor device including a cell stack including semiconductor patterns spaced apart from one another in a first horizontal direction and a vertical direction, word lines surrounding the semiconductor patterns and extending in the first horizontal direction, bit lines connected to a first end of each of the semiconductor patterns and extending in the vertical direction, and cell capacitors connected to a second end of each of the semiconductor patterns, a peripheral circuit stack on the cell stack and including a peripheral circuit substrate on the cell stack, and a peripheral circuit transistor on the peripheral circuit substrate, a connection via extending in the vertical direction through the peripheral circuit substrate, a front pad on a top surface of the peripheral circuit stack and electrically connected to the connection via, and a rear pad on a bottom surface of the cell stack and electrically connected to the connection via.

### CROSS-REFERENCE TO RELATED APPLICATIONS

This present application claims priority to and the benefit under 35 U.S.C. § 119(a)-(d) of Korean Patent Application No. 10-2025-0024515, filed on Feb. 25, 2025, in the Korean Intellectual Property Office, the entire disclosure of which is incorporated herein by reference.

### FIELD

Disclosed concepts relate to a semiconductor device, and more particularly, to a semiconductor device having a structure where a plurality of dies are stacked.

### BACKGROUND

To enhance the performance and storage capacity of semiconductor devices, semiconductor devices having a structure where a plurality of dies are stacked are widely used. In addition, a higher degree of integration is required to provide high-capacity semiconductor devices. Thus, three-dimensional semiconductor devices are being proposed that increase memory capacity by stacking multiple memory cells vertically on a substrate.

### SUMMARY

The disclosed concepts provide a semiconductor device having a structure where a plurality of semiconductor dies are stacked, including a three-dimensional semiconductor device capable of having increased memory capacity.

According to aspects of disclosed concepts, there is provided a semiconductor device including a cell stack including a plurality of semiconductor patterns spaced apart from one another in a first horizontal direction and a vertical direction, a plurality of word lines surrounding the plurality of semiconductor patterns and extending in the first horizontal direction, a plurality of bit lines connected to a first end of each of the plurality of semiconductor patterns and extending in the vertical direction, and a plurality of cell capacitors connected to a second end of each of the plurality of semiconductor patterns and spaced apart from one another in the vertical direction, a peripheral circuit stack disposed on the cell stack, the peripheral circuit stack including a peripheral circuit substrate disposed on a top surface of the cell stack, and a peripheral circuit transistor disposed on the peripheral circuit substrate, a connection via extending in the vertical direction through the peripheral circuit substrate, a front pad disposed on a top surface of the peripheral circuit stack and electrically connected to the connection via, and a rear pad disposed on a bottom surface of the cell stack and electrically connected to the connection via.

According to aspects of disclosed concepts, there is provided a semiconductor device including a cell stack including a plurality of semiconductor patterns spaced apart from one another in a first horizontal direction and a vertical direction, a plurality of word lines surrounding the plurality of semiconductor patterns and extending in the first horizontal direction, a plurality of bit lines connected to a first end of each of the plurality of semiconductor patterns and extending in the vertical direction, a plurality of cell capacitors connected to a second end of each of the plurality of semiconductor patterns and spaced apart from one another in the vertical direction, a cover insulating layer arranged to cover the plurality of word lines, and a bottom insulating layer disposed on a bottom surface of the plurality of word lines, a peripheral circuit stack disposed on the cell stack, the peripheral circuit stack including a peripheral circuit substrate disposed on a top surface of the cell stack, and a peripheral circuit transistor disposed on the peripheral circuit substrate, a connection via extending in the vertical direction through the peripheral circuit substrate, a front pad disposed on a top surface of the peripheral circuit stack and electrically connected to the connection via, and a rear pad disposed on a bottom surface of the cell stack, and disposed on a bottom surface of the bottom insulating layer and electrically connected to the connection via.

According to aspects of disclosed concepts, there is provided a semiconductor device including a plurality of dies stacked in a vertical direction, wherein each of the plurality of dies includes a cell stack including a plurality of semiconductor patterns spaced apart from one another in a first horizontal direction and the vertical direction, a plurality of word lines surrounding the plurality of semiconductor patterns and extending in the first horizontal direction, a plurality of bit lines connected to a first end of each of the plurality of semiconductor patterns and extending in the vertical direction, a plurality of cell capacitors connected to a second end of each of the plurality of semiconductor patterns and spaced apart from one another in the vertical direction, a cover insulating layer arranged to cover the plurality of word lines, and a bottom insulating layer disposed on a bottom surface of the plurality of word lines, a peripheral circuit stack disposed on the cell stack, the peripheral circuit stack including a peripheral circuit substrate disposed on a top surface of the cell stack, and a peripheral circuit transistor disposed on the peripheral circuit substrate, a connection via extending in the vertical direction through the peripheral circuit substrate, a front pad disposed on a top surface of the peripheral circuit stack and electrically connected to the connection via, and a rear pad disposed on a bottom surface of the cell stack and electrically connected to the connection via.

According to aspects of disclosed concepts, there is provided a method of manufacturing a semiconductor device includes providing a peripheral circuit stack including a peripheral circuit substrate and a peripheral circuit transistor arranged on the peripheral circuit substrate, forming a cell stack on a cell wafer, wherein the cell stack includes a plurality of semiconductor patterns spaced apart from one another in a first horizontal direction and a vertical direction, a plurality of word lines surrounding the plurality of semiconductor patterns and extending in the first horizontal direction, a plurality of bit lines connected to a first end of each of the plurality of semiconductor patterns and extending in the vertical direction, and a plurality of cell capacitors connected to a second end of each of the plurality of semiconductor patterns and spaced apart from one another in the vertical direction, bonding the cell stack to the peripheral circuit stack, forming a connection via extending vertically through the peripheral circuit stack, removing the cell wafer, forming a front pad electrically connected to the connection via on a top surface of the peripheral circuit stack, and forming a rear pad electrically connected to the connection via on a bottom surface of the cell stack.

In embodiments, the cell stack may further include an upper wiring layer electrically connected to the plurality of word lines or the plurality of cell capacitors, and an upper insulating layer covering the upper wiring layer.

In embodiments, the bonding of the cell stack to the peripheral circuit stack may include bonding the cell stack to the peripheral circuit stack such that a bottom surface of the peripheral circuit substrate is in contact with the upper insulating layer.

In embodiments, the upper wiring layer may include a landing pad wiring layer that contacts the bottom surface of the connection via.

In embodiments, the method may further include forming a connection via hole penetrating a portion of the peripheral circuit substrate and the upper insulating layer, prior to the forming of the connection via, and forming a connection via insulating layer on an inner wall of the connection via hole.

In embodiments, in the forming of the connection via hole, the top surface of the landing pad wiring layer may be exposed at the bottom of the connection via hole.

In embodiments, the cell stack may further include a cover insulating layer covering the plurality of word lines and the plurality of cell capacitors, and a cell connection via extending in the vertical direction through the cover insulating layer and electrically connected to the landing pad wiring layer.

In embodiments, the cell connection via may be arranged at a position that vertically overlaps the landing pad wiring layer, and the connection via may be arranged at a position that vertically overlaps the landing pad wiring layer.

In embodiments, after the removing of the cell wafer from the cell stack, the method may further include removing a portion of the cover insulating layer from the bottom surface of the cell stack to form a via hole, forming the cell connection via within the via hole.

In embodiments, after the removing of the cell wafer, bonding the cell stack to the peripheral circuit stack may be performed.

According to aspects of disclosed concepts, there is provided a method of manufacturing a semiconductor device including: providing a cell stack including a plurality of semiconductor patterns spaced apart from one another in a first horizontal direction and a vertical direction,, a plurality of word lines surrounding the plurality of semiconductor patterns and extending in the first horizontal direction, a plurality of bit lines connected to a first end of each of the plurality of semiconductor patterns and extending in the vertical direction, and a plurality of cell capacitors connected to a second end of each of the plurality of semiconductor patterns and spaced apart from one another in the vertical direction; providing a peripheral circuit stack disposed on the cell stack, the peripheral circuit stack including a peripheral circuit substrate disposed on a top surface of the cell stack, and a peripheral circuit transistor disposed on the peripheral circuit substrate; providing a connection via extending in the vertical direction through the peripheral circuit substrate; providing a front pad disposed on a top surface of the peripheral circuit stack and electrically connected to the connection via; and providing a rear pad disposed on a bottom surface of the cell stack and electrically connected to the connection via.

### BRIEF DESCRIPTION OF THE DRAWINGS

Embodiments will be more clearly understood from the following detailed description taken in conjunction with the accompanying drawings in which:

FIG. 1 is a schematic diagram of a semiconductor device according to embodiments;

FIG. 2 is a cross-sectional view of portion A-A′ in FIG. 1;

FIG. 3 is a circuit diagram of a memory cell array included in a cell stack in FIG. 1;

FIG. 4 is a schematic perspective view of the memory cell array of FIG. 3;

FIG. 5 is a cross-sectional view of portion B1-B1′ in FIG. 4;

FIG. 6 is a cross-sectional view of portion B2-B2′ in FIG. 4;

FIG. 7 is a cross-sectional view of a semiconductor device according to embodiments;

FIG. 8 is a cross-sectional view of a semiconductor device according to embodiments;

FIG. 9 is a cross-sectional view of a semiconductor device according to embodiments;

FIG. 10 is a schematic diagram of a semiconductor device according to embodiments;

FIGS. 11A to 11H are schematic diagrams illustrating a method of manufacturing the semiconductor device, according to embodiments;

FIGS. 12A to 12F are schematic diagrams illustrating a method of manufacturing the semiconductor device, according to embodiments;

FIGS. 13A to 13F are schematic diagrams illustrating a method of manufacturing the semiconductor device, according to embodiments; and

FIGS. 14A to 14E are schematic diagrams illustrating a method of manufacturing the semiconductor device, according to embodiments.

### DETAILED DESCRIPTION

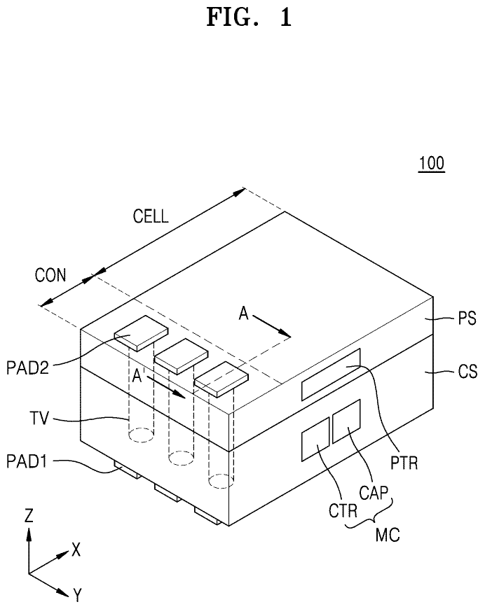

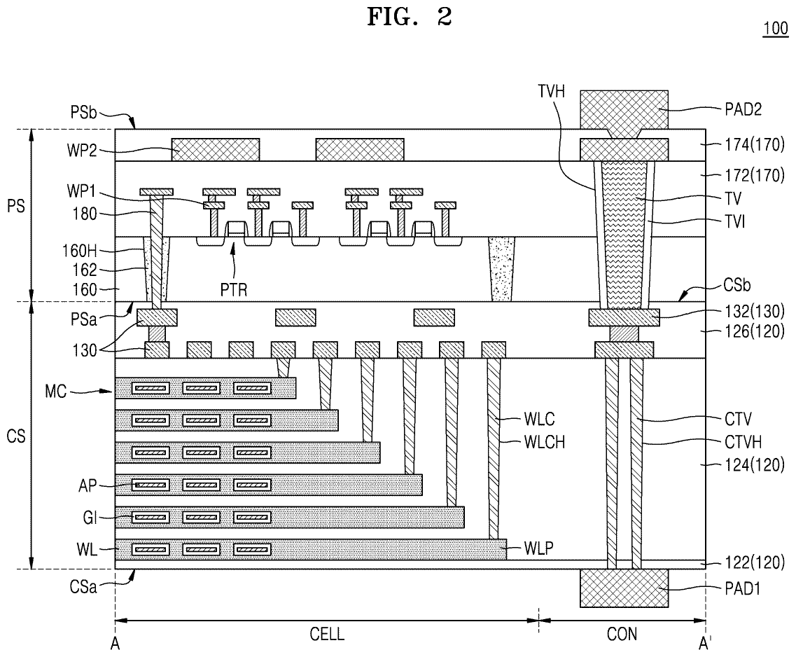

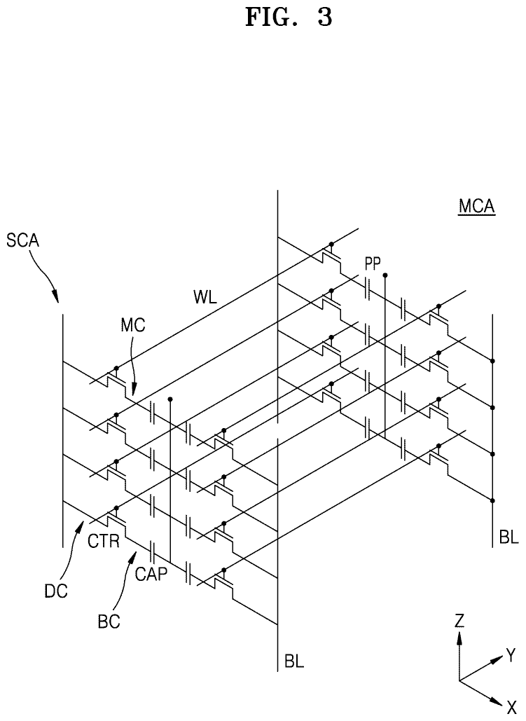

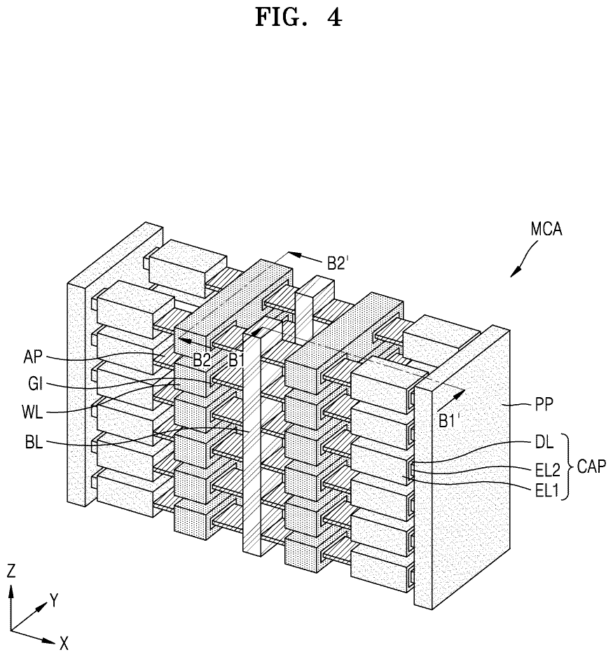

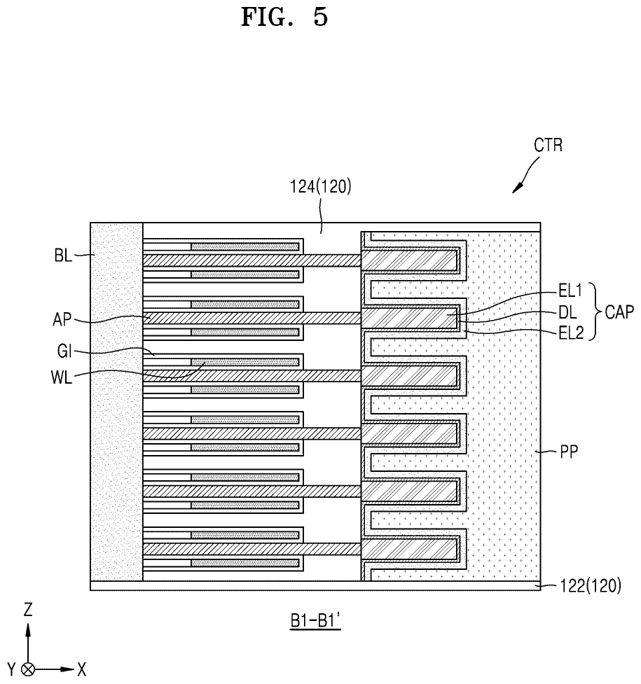

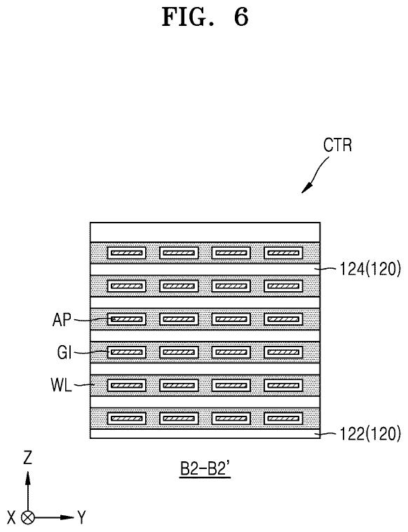

FIG. 1 is a schematic diagram of a semiconductor device 100 according to embodiments. FIG. 2 is a cross-sectional view of portion A-A′ in FIG. 1. FIG. 3 is a circuit diagram of a memory cell array MCA included in a cell stack in FIG. 1. FIG. 4 is a schematic perspective view of the memory cell array MCA of FIG. 3. FIG. 5 is a cross-sectional view of portion B1-B1′ in FIG. 4. FIG. 6 is a cross-sectional view of portion B2-B2′ in FIG. 4.

Referring to FIGS. 1 to 6, the semiconductor device 100 may include a cell stack CS and a peripheral circuit stack PS on the cell stack CS. The semiconductor device 100 may include a semiconductor device having a peripheral-over-cell (POC) structure in that the peripheral circuit stack PS is disposed on the cell stack CS.

In embodiments, the cell stack CS may include a memory cell region of a dynamic random-access memory (DRAM) device. In embodiments, the cell stack CS may include a plurality of memory cells stacked in a vertical direction Z. Each memory cell may include a cell transistor CTR and a cell capacitor CAP, wherein the cell transistor CTR and the cell capacitor CAP may be arranged in a horizontal direction. The cell stack CS may include the DRAM device having a one-transistor, one-capacitor (1T1C) structure in which one cell transistor CTR is electrically connected to one cell capacitor CAP.

In embodiments, the peripheral circuit stack PS may include a core region or a peripheral circuit region of the DRAM device. The peripheral circuit stack PS may include a peripheral circuit transistor PTR for transmitting a signal and/or a power supply to the cell transistor CTR and the cell capacitor CAP included in the cell stack CS. In embodiments, the peripheral circuit transistor PTR may include various circuits, such as a command decoder, a control logic, an address buffer, a row decoder, a column decoder, a sense amplifier, and a data input/output circuit.

In embodiments, the peripheral circuit stack PS may be attached onto the cell stack CS by a bonding method. In embodiments, the peripheral circuit stack PS may be attached onto the cell stack CS by an oxide bonding method.

In embodiments, the semiconductor device 100 may include a cell region CELL and a connection region CON. The cell region CELL may include a region in which the cell transistor CTR, the cell capacitor CAP, and the peripheral circuit transistor PTR are arranged, and the connection region CON may include a region in which a connection via TV, a rear pad PAD1, and a front pad PAD2 are arranged.

In embodiments, the connection via TV arranged in the connection region CON may extend in the vertical direction Z through at least a portion of the peripheral circuit stack PS. The rear pad PAD1 may be disposed on the bottom surface of the cell stack CS and may be electrically connected to the connection via TV through a cell connection via CTV. The front pad PAD2 may be disposed on the top surface of the peripheral circuit stack PS and may be electrically connected to the connection via TV.

In embodiments, the cell stack CS may have a first surface CSa which is a rear surface, and a second surface CSb which is a front surface. The peripheral circuit stack PS may have a first surface PSa which is a rear surface, and a second surface PSb which is a front surface. The first surface PSa of the peripheral circuit stack PS may be disposed on the second surface CSb of the cell stack CS. This structure may be referred to as a structure in which the front surface (e.g., the second surface CSb) of the cell stack CS and the rear surface (e.g., the first surface PSa) of the peripheral circuit stack PS are bonded to one another.

The front surface of the cell stack CS may refer to a top surface of the cell stack CS formed on a cell wafer in the process of forming the cell stack CS, and the rear surface of the cell stack CS may refer to a bottom surface of the cell stack CS in contact with the cell wafer in the process of forming the cell stack CS. In addition, the rear surface of the peripheral circuit stack PS may refer to a bottom surface of a peripheral circuit substrate 160, and the front surface of the peripheral stack PS may refer to a top surface of the peripheral stack PS opposite to the bottom surface of the peripheral circuit substrate 160.

In embodiments, the cell stack CS may include the memory cell array MCA shown in FIGS. 3 to 6. The memory cell array MCA may include a plurality of sub-cell arrays SCA. The plurality of sub-cell arrays SCA may be spaced apart from one another in a second horizontal direction Y.

The sub-cell array SCA may include a plurality of bit lines BL, a plurality of word lines WL, and a plurality of memory cells MC. Each of the plurality of memory cells MC may include one cell transistor CTR and one cell capacitor CAP connected thereto. Each of the plurality of memory cells MC may have a 1T1C structure.

The plurality of word lines WL may extend in the second horizontal direction Y and may be spaced apart from one another in a first horizontal direction X and the vertical direction Z. The plurality of bit lines BL may extend in the vertical direction Z and may be spaced apart from one another in each of the first horizontal direction X and the second horizontal direction Y. One cell transistor CTR may be arranged between one word line WL and one bit line BL.

A gate of the cell transistor CTR may be connected to the word line WL, and a source of the cell transistor CTR may be connected to the bit line BL through a first contact DC. The cell transistor CTR may be connected to the cell capacitor CAP through a second contact BC. A drain of the cell transistor CTR may be connected to a first electrode of the cell capacitor CAP through the second contact BC, and a second electrode of the cell capacitance CAP may be connected to a plate electrode PP.

In one sub-cell array SCA, a plurality of cell transistors CTR may be arranged at positions where the plurality of cell transistors CTR overlap one another in the vertical direction Z. In one sub-cell array SCA, a plurality of cell capacitors CAP may be arranged at positions where the plurality of cell capacitors CAP overlap one another in the vertical direction Z. One cell transistor CTR and one cell capacitor CAP may be arranged side by side at the same vertical level, and a plurality of memory cells MC each composed of one cell transistor CTR and one cell capacitor CAP may be stacked in the vertical direction Z. The storage capacity of the sub-cell array SCA may vary depending on the number of memory cells MC or the number of layers of memory cells MC (e.g., the number of cell capacitors CAP or the number of layers of cell capacitors CAP) stacked in the vertical direction Z.

As shown in FIG. 4, a plurality of semiconductor patterns AP may extend in the first horizontal direction X and may be spaced apart from one another in the second horizontal direction Y and the vertical direction Z. In embodiments, the plurality of semiconductor patterns AP may include, for example, an undoped semiconductor material or a doped semiconductor material. In embodiments, the plurality of semiconductor patterns AP may include polysilicon. In embodiments, the plurality of semiconductor patterns AP may include an amorphous metal oxide, a polycrystalline metal oxide, or a combination of the amorphous metal oxide and the polycrystalline metal oxide. For example, the plurality of semiconductor patterns AP may include at least one of an In-Ga-based oxide (IGO), an In-Zn-based oxide (IZO), or an In—Ga—Zn-based oxide (IGZO). In embodiments, the plurality of semiconductor patterns AP may include a two-dimensional (2D) material semiconductor. For example, the 2D material semiconductor may include MoS₂, WSe₂, graphene, carbon nanotube, or a combination thereof.

The plurality of word lines WL may be spaced apart from one another in the vertical direction Z and may be respectively disposed on the top surface, the bottom surface, and the sidewalls of the plurality of semiconductor patterns AP to extend in the second horizontal direction Y. One word line WL among the plurality of word lines WL may extend in the second horizontal direction Y, surrounding the plurality of semiconductor patterns AP spaced apart from one another in the second horizontal direction Y. Two word lines WL that are spaced apart from one another in the vertical direction Z among the plurality of word lines WL may be arranged at positions where the two word lines WL overlap one another in the horizontal direction Z. The semiconductor device 100 may be referred to as a gate-all-around-type device as the plurality of word lines WL surround the top surface, the bottom surface, and the sidewalls of the semiconductor patterns AP. In embodiments, the plurality of word lines WL may include at least one of Ti, TiN, TiAlC, TiAlN, TiSiN, Mo, MoN, MoSiN, W, WN, WSiN, Ta, TaN, TaSiN, or LaN.

In embodiments, a gate insulating layer GI may be arranged between the word line WL and the semiconductor pattern AP. The gate insulating layer GI may include at least one selected from a ferroelectric material and a high-k dielectric material having a dielectric constant that is higher than that of silicon oxide. In embodiments, the gate insulating layer GI may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconium titanium oxide (PbZrTiO), strontium tantalum bismuth oxide (SrTaBiO), bismuth iron oxide (BiFeO), strontium titanium oxide (SrTiO), yttrium oxide (YO), aluminum oxide (AlO), or lead scandium tantalum oxide (PbScTaO).

First ends of the plurality of semiconductor patterns AP may be connected to the plurality of bit lines BL. The plurality of bit lines BL may extend in the vertical direction Z and may be spaced apart from one another in the second horizontal direction Y. The plurality of bit lines BL may include one of a doped semiconductor material, a conductive metal nitride, a metal, or a metal-semiconductor compound.

In embodiments, the cell capacitor CAP may include a first electrode EL1, a capacitor dielectric layer DL, and a second electrode EL2. The cell capacitor CAP may include a metal-insulator-metal (MIM)-type capacitor.

In embodiments, the first electrode EL1 may be connected to a second end of the semiconductor pattern AP. The first electrode EL1 may have a bar shape or a pillar shape extending in the first horizontal direction X. In embodiments, the first electrode EL1 may have a cup shape or U-shape rotated by 90 degrees. In embodiments, a plurality of first electrodes EL1 may be arranged at positions where the plurality of first electrodes EL1 overlap one another in the vertical direction Z.

In embodiments, the capacitor dielectric layer DL may be disposed on the first electrode EL1. For example, the capacitor dielectric layer DL may be conformally disposed on the top surface, the bottom surface, and the sidewalls of the first electrode EL1.

In embodiments, the second electrode EL2 may be disposed on the capacitor dielectric layer DL and may be conformally disposed on the top surface, the bottom surface, and the sidewalls of the capacitor dielectric layer DL. For example, the capacitor dielectric layer DL may be arranged between the first electrode EL1 and the second electrode EL2.

In embodiments, the first electrode EL1 and the second electrode EL2 may include a doped semiconductor material, a conductive metal nitride, such as titanium nitride, tantalum nitride, niobium nitride, or tungsten nitride, a metal, such as ruthenium, iridium, titanium, or tantalum, and a conductive metal oxide, such as iridium oxide or niobium oxide. In embodiments, the capacitor dielectric layer DL may include at least one selected from a ferroelectric material and a high-k dielectric material having a dielectric constant that is higher than that of silicon oxide. In embodiments, the capacitor dielectric layer DL may include at least one material selected from HfO, HfSiO, HfON, HfSiON, LaO, LaAlO, ZrO, ZrSiO, ZrON, ZrSiON, TaO, TiO, BaSrTiO, BaTiO, PbZrTiO, SrTaBiO, BiFeO, SrTiO, YO, AlO, or PbScTaO.

The plate electrode PP may be disposed on one side of the cell capacitor CAP to extend in the vertical direction Z and the second horizontal direction Y. The second electrode EL2 of the cell capacitor CAP may be electrically connected to the plate electrode PP.

In embodiments, a memory device, such as a variable resistance memory device, a phase-change memory device, or a magnetic memory device, may be arranged instead of the cell capacitor CAP.

In embodiments, the cell stack CS may further include a plurality of word line pads WLP. Each of the plurality of word line pads WLP may be connected to the plurality of word lines WL. The plurality of word line pads WLP may vary in length in the horizontal direction. Thus, the plurality of word line pads WLP may have a step shape.

In embodiments, an insulating layer 120 may be disposed on the top surface and the bottom surface of the plurality of word lines WL, and on the top surface of the plurality of word line pads WLP. In embodiments, the insulating layer 120 may cover the entire memory cell MC and may electrically separate some components of each memory cell MC from other components.

In embodiments, the insulating layer 120 may include a bottom insulating layer 122, a cover insulating layer 124, and an upper insulating layer 126. In embodiments, the bottom insulating layer 122 may be disposed on the bottom surface of the lowermost word line WL. The cover insulating layer 124 may be arranged between the plurality of word lines WL and arranged on the top surfaces of the plurality of word line pads WLP. The upper insulating layer 126 may be formed on the cover insulating layer 124.

Although it is shown in FIG. 2 that the insulating layer 120 includes the bottom insulating layer 122, the cover insulating layer 124, and the upper insulating layer 126, the detailed structure of the insulating layer 120 may vary depending on the manufacturing process of the memory cell MC. For example, the insulating layer 120 may have a structure where a plurality of insulating layers are stacked. A boundary between some of the plurality of insulating layers may or may not be clearly identified.

The cell stack CS may further include an upper wiring layer 130 surrounded by the insulating layer 120. The upper wiring layer 130 may be electrically connected to components of the memory cell MC of the cell stack CS, for example, the bit line BL, the word line WL, or the cell capacitor CAP. In embodiments, the upper wiring layer 130 may be disposed on a top surface of the cover insulating layer 124, and the upper insulating layer 126 may be disposed on the upper wiring layer 130. In embodiments, the upper wiring layer 130 may have a structure where two or more metal wiring layers having different vertical levels are stacked, and the upper insulating layer 126 may have a structure where the plurality of insulating layers are stacked to cover the two or more metal wiring layers.

In embodiments, a portion of the upper wiring layer 130 may be electrically connected to the word line pad WLP through the word line contact WLC. The word line contact WLC may extend in the vertical direction Z through the cover insulating layer 124, and sidewalls of the word line contact WLC may be surrounded by the cover insulating layer 124. The word line contact WLC may have a length that varies depending on the vertical level of the corresponding word line pad WLP. In embodiments, a width of the top surface of the word line contact WLC may be greater than a width at the bottom surface of the word line contact WLC. The word line contact WLC may have a width that gradually decreases in a direction from the top surface toward the bottom surface of the word line contact WLC, but disclosed concepts are not limited thereto.

The upper wiring layer 130 may further include a landing pad wiring layer 132 arranged in the connection region CON. In embodiments, the connection via TV may be placed on a top surface of the landing pad wiring layer 132, and the top surface of the landing pad wiring layer 132 may be in contact with a bottom surface of the connection via TV.

In embodiments, the peripheral circuit stack PS may include the peripheral circuit substrate 160 and a peripheral circuit transistor PTR disposed on the peripheral circuit substrate 160.

In embodiments, the peripheral circuit substrate 160 may be arranged at a higher vertical level than the cell stack CS. In embodiments, the peripheral circuit substrate 160 may be disposed on the top surface of the cell stack CS, e.g., on the top surface of the upper insulating layer 126. In embodiments, the bottom surface of the peripheral circuit substrate 160 may be in contact with the top surface of the upper insulating layer 126.

In embodiments, the peripheral circuit substrate 160 may include silicon, for example, single crystal silicon, polycrystalline silicon, or amorphous silicon. In embodiments, the peripheral circuit substrate 160 may include at least one selected from Ge, SiGe, SiC, GaAs, InAs, or InP.

The peripheral circuit transistor PTR may be disposed on a top surface of the peripheral circuit substrate 160. The peripheral circuit transistor PTR may include at least one of a planar-type transistor, a finFET transistor, a multi-bridge channel transistor, or a buried channel array transistor.

The peripheral circuit transistor PTR and wiring patterns WP1 and WP2 electrically connected to the peripheral circuit substrate 160 may be disposed on the top surface of the peripheral circuit substrate 160, and a wiring insulating layer 170 covering the peripheral circuit transistor PTR and the wiring patterns WP1 and WP2 may be disposed on the top surface of the peripheral circuit substrate 160.

In embodiments, a via hole 160H may pass through the peripheral circuit substrate 160, and a via insulating layer 162 may be arranged in the via hole 160H. The through via contact 180 may extend in the vertical direction Z through the via insulating layer 162, and the wiring patterns WP1 and WP2 may be electrically connected to the upper wiring layer 130 by the through via contact 180.

In embodiments, a width of the top surface of the through via contact 180 may be greater than that of the bottom surface of the through via contact 180. For example, the through via contact 180 may have a horizontal width that gradually decreases in a direction from the top surface to the bottom surface of the through via contact 180, but disclosed concepts are not limited thereto.

The through via contact 180 may function as an electrical connection member for electrically connecting the peripheral circuit transistor PTR disposed on the top surface of the peripheral circuit substrate 160 to the memory cell MC arranged in the cell stack CS. For example, through the through via contact 180, the peripheral circuit transistor PTR disposed on the top surface of the peripheral circuit substrate 160 may be electrically connected to the bit line BL, the word line WL, or the plate electrode PP of the memory cell MC and may provide a power source and an electrical signal for driving the memory cell MC.

The connection via TV may be arranged in the connection region CON of the semiconductor device 100, and the connection via TV may extend in the vertical direction Z through at least a portion of the peripheral circuit stack PS. In embodiments, the connection via hole TVH may extend in the vertical direction Z through the peripheral circuit substrate 160 and a first insulating layer 172, and the bottom of the connection via hole TVH may extend into the upper insulating layer 126 of the cell stack CS. The top surface of the landing pad wiring layer 132 may be exposed at the bottom of the connection via hole TVH.

A connection via insulating layer TVI may be conformally disposed on the inner wall of the connection via hole TVH, and the connection via TV filling the inside of the connection via hole TVH may be disposed on the connection via insulating layer TVI. A portion of the connection via insulating layer TVI may be arranged between the connection via TV and the peripheral circuit substrate 160 so that the connection via TV is electrically insulated from the peripheral circuit substrate 160.

In embodiments, the connection via TV may include copper, copper alloy, titanium, silver, platinum, or a combination thereof. In embodiments, the connection via insulating layer TVI may include silicon oxide, silicon nitride, silicon oxynitride, or a combination thereof.

In embodiments, the connection via TV may be formed by attaching the peripheral circuit stack PS to the cell stack CS, then forming the connection via hole TVH passing through the peripheral circuit stack PS, and then filling the connection via hole TVH with a metal material.

In embodiments, a width of the top surface of the connection via TV may be greater than a width of the bottom surface of the connection via TV. In a direction from the top surface to the bottom surface of the connection via TV, the width of the connection via TV may gradually decrease.

In embodiments, the connection via TV may have a top surface arranged at the same level as a top surface of the first insulating layer 172. The bottom of the connection via TV may be covered by the upper insulating layer 126. In embodiments, the connection via insulating layer TVI may be arranged between the bottom of the connection via TV and the upper insulating layer 126. The bottom surface of the connection via TV may be arranged at a lower vertical level than a bottom surface of the peripheral circuit stack PS. The bottom surface of the connection via TV may be in contact with the top surface of the landing pad wiring layer 132 in the cell stack CS.

In embodiments, the second wiring pattern WP2 may be disposed on the top surface of the connection via TV, and a second insulating layer 174 may be disposed on a top surface of the second wiring pattern W2. The front pad PAD2 may be disposed on the second insulating layer 174, and the front pad PAD2 may be electrically connected to the connection via TV through the second wiring pattern WP2.

In embodiments, the second wiring pattern WP2 between the top surface of the connection via TV and the front pad PAD2 may be omitted, and the top surface of the connection via TV may be in direct contact with the front pad PAD2.

The cell stack CS may further include the cell connection via CTV electrically connected to the landing pad wiring layer 132. The cell connection via CTV may extend in the vertical direction Z through the cover insulating layer 124 at a position where the cell connection via CTV vertically overlaps the landing pad wiring layer 132, and a top surface of the cell connection via CTV may be in contact with the landing pad wiring layer 132. The bottom surface of the cell connection via CTV may extend through the bottom insulating layer 122 and may be in contact with the rear pad PAD1.

In embodiments, a width of the top surface of the cell connection via CTV may be greater than a width of the bottom surface of the cell connection via CTV. In a direction from the top surface to the bottom surface of the cell connection via CTV, the width of the cell connection via CTV may gradually decrease.

In embodiments, as shown in FIG. 4, a plurality of cell connection vias CTV may be arranged to correspond to one landing pad wiring layer 132 or one rear pad PAD1. The plurality of cell connection vias CTV may be commonly electrically connected to one rear pad PAD1. However, disclosed concepts are not limited thereto, and one cell connection via CTV may be arranged to correspond to one rear pad PAD1.

In embodiments, the cell connection via CTV may be formed together in at least a portion of an etch process and a metal layer filling process for forming the word line contact WLC. In embodiments, portions of the cover insulating layer 124 may be removed to form a contact hole WLCH and a via hole CTVH, and a conductive material may be used in the contact hole WLCH and the via hole CTVH to form the word line contact WLC and the cell connection via CTV, respectively. However, the method of manufacturing the cell connection via CTV is not limited to the above.

In embodiments, the word line contact WLC and the cell connection via CTV may include tungsten, tungsten nitride, titanium, titanium nitride, ruthenium, cobalt, cobalt nitride, molybdenum, molybdenum nitride, or a combination thereof.

According to embodiments, the semiconductor device 100 may include the cell stack CS including a three-dimensional semiconductor device, and the peripheral circuit stack PS disposed on the cell stack CS. The semiconductor device 100 may include the connection via TV extending through the peripheral circuit stack PS. The rear pad PAD1 and the front pad PAD2 may be electrically connected to the connection via TV. The semiconductor device 100 may have a high degree of integration while having excellent electrical performance.

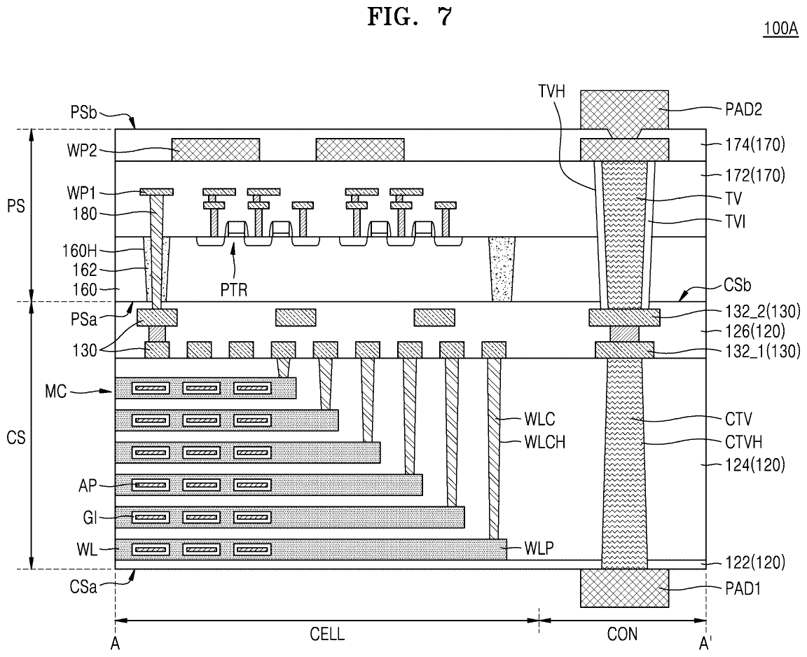

FIG. 7 is a cross-sectional view of a semiconductor device 100A according to embodiments.

Referring to FIG. 7, the upper wiring layer 130 may include a first landing pad wiring layer 132_1 and a second landing pad wiring layer 132_2. The second landing pad wiring layer 132_2 may be electrically connected to the first landing pad wiring layer 132_1 at a higher vertical level than the first landing pad wiring layer 132_1.

In embodiments, the first landing pad wiring layer 132_1 may have a bottom surface in contact with the top surface of the cell connection via CTV, and the second landing pad wiring layer 132_2 may have a top surface in contact with the bottom surface of the connection via TV.

In embodiments, a width of the top surface of the cell connection via CTV may be less than a width of the bottom surface of the cell connection via CTV. For example, the cell connection via CTV may have a width that gradually increases in a direction from the top surface to the bottom surface of the cell connection via CTV.

In embodiments, the cell connection via CTV may be formed by removing a portion of the bottom insulating layer 122 and a portion of the cover insulating layer 124 from the bottom surface (first surface CSa) of the cell stack CS to form the via hole CTVH and then filling the via hole CTVH with a conductive material. In an etching process for forming the via hole CTVH, the bottom surface of the first landing pad wiring layer 132_1 may be exposed at an end of the via hole CTVH, and the cell connection via CTV may have an end in contact with the bottom surface of first landing pad wiring layer 132_1.

In embodiments, the cell connection via CTV may include a combination of copper, copper alloy, titanium, silver, platinum, and the like. In embodiments, the cell connection via CTV may include tungsten, tungsten nitride, titanium, titanium nitride, ruthenium, cobalt, cobalt nitride, molybdenum, molybdenum nitride, or a combination thereof.

In embodiments, the cell connection via CTV may be arranged such that one cell connection via CTV corresponds to one rear pad PAD1. In embodiments, the plurality of cell connection vias CTV may be arranged to correspond to one landing pad wiring layer 132 or one rear pad PAD1, and the plurality of cell connection vias CTV may commonly be electrically connected to one rear pad PAD1.

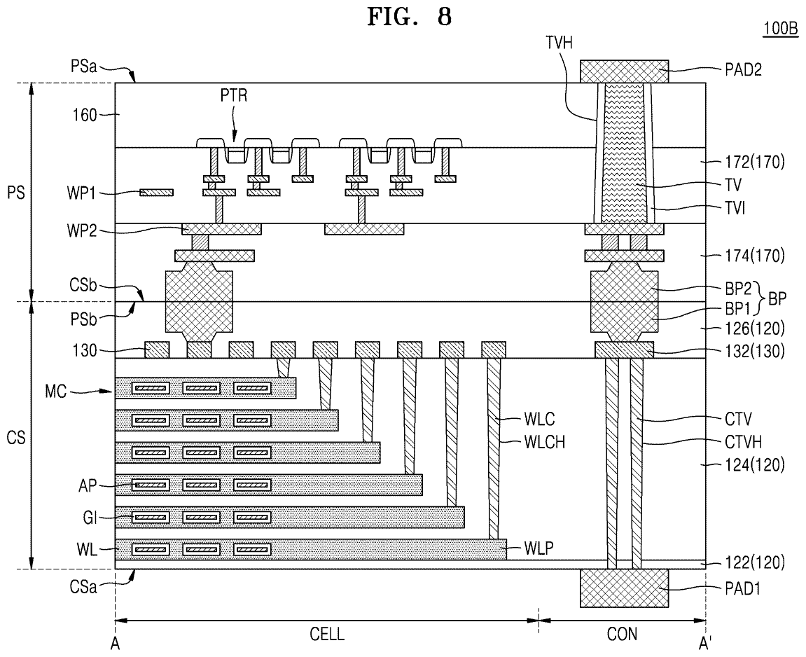

FIG. 8 is a cross-sectional view of a semiconductor device 100B according to embodiments.

Referring to FIG. 8, the semiconductor device 100B may include a cell stack CS and a peripheral circuit stack PS on the cell stack CS. The cell stack CS may have a first surface CSa which is a rear surface, and a second surface CSb which is a front surface. The peripheral circuit stack PS may have a first surface PSa which is a rear surface, and the second surface PSb which is a front surface. The second surface PSb of the peripheral circuit stack PS may be disposed on the second surface CSb of the cell stack CS. Such a structure may be referred to as a structure where the front surface (e.g., the second surface CSb) of the cell stack CS is bonded to the front surface (e.g., the second surface PSb) of the peripheral circuit stack PS.

The front surface or the second surface CSb of the cell stack CS may refer to the top surface of the cell stack CS formed on the cell wafer in the process of forming the cell stack CS. The front surface or the second surface CSb of the cell stack CS may include the top surface of the upper insulating layer 126. The rear surface or first surface CSa of the cell stack CS may refer to the bottom surface of the cell stack CS that contacts the cell wafer in the process of forming the cell stack CS. The rear surface or the first surface CSa of the cell stack CS may refer to the bottom surface of the bottom insulating layer 122.

When the peripheral circuit transistor PTR is disposed on the second surface of the peripheral circuit substrate 160 and the first surface of the peripheral circuit substrate 160 is opposite to the second surface thereof, the rear surface or the first surface PSa of the peripheral circuit stack PS may refer to the first surface (e.g., the top surface of the peripheral circuit substrate 160 shown in FIG. 8) of the peripheral circuit substrate 160. The front surface or the second surface PSb of the peripheral circuit stack PS may refer to a surface (e.g., the bottom surface of the peripheral circuit stack PS shown in FIG. 8) of the peripheral circuit stack PS arranged opposite to the first surface of the peripheral circuit substrate 160.

In embodiments, the peripheral circuit stack PS may include a wiring insulating layer 170 that covers the peripheral circuit transistor PTR and the first and second wiring patterns WP1 and WP2. The wiring insulating layer 170 may include a first insulating layer 172 adjacent to the peripheral circuit substrate 160, and a second insulating layer 174, wherein the first insulating layer 172 is arranged between the peripheral circuit substrate 160 and the second insulating layer 174.

In embodiments, the connection via TV may be arranged in the connection via hole TVH extending in the vertical direction Z through the first insulating layer 172 and the peripheral circuit substrate 160. The connection via insulating layer TVI may be disposed on a sidewall of the connection via TV in the connection via hole TVH. As a portion of the connection via insulating layer TVI is arranged between the connection via TV and the peripheral circuit substrate 160, the connection via TV may be electrically insulated from the peripheral circuit substrate 160.

In embodiments, a width of the top surface of the connection via TV may be less than a width at the bottom surface of the connection via TV. In the direction from the top surface to the bottom surface of the connection via TV, the width of the connection via TV may gradually increase.

In embodiments, the cell stack CS may be attached to the peripheral circuit stack PS by a metal-oxide hybrid bonding method. In embodiments, a bonding pad BP including a first bonding pad BP1 and a second bonding pad BP2 may be provided at the interface between the cell stack CS and the peripheral circuit stack PS. The first bonding pad BP1 may be arranged in the cell stack CS and may have a top surface arranged at the same level as the top surface of the upper insulating layer 126 included in the cell stack CS. The second bonding pad BP2 may be arranged in the peripheral circuit stack PS and may have a bottom surface arranged at the same level as the bottom surface of the second insulating layer 174 included in the peripheral circuit stack PS.

In embodiments, the top surface of the first bonding pad BP1 may be in contact with the bottom surface of the second bonding pad BP2. The contact interface between the top surface of first bonding pad BP1 and the bottom surface of the second bonding pad BP2 may be arranged substantially coplanar with the contact interface between the top surface of the upper insulating layer 126 and the bottom surface of the second insulating layer 174 (i.e., the contact interfaces may be arranged substantially at the same vertical level and continuously connected to one another).

In embodiments, the cell connection via CTV may extend in the vertical direction Z through the cover insulating layer 124 at the position where the cell connection via CTV vertically overlaps the landing pad wiring layer 132. The top surface of the cell connection via CTV may be in contact with the landing pad wiring layer 132. The bottom surface of the cell connection via CTV may extend through the bottom insulating layer 122 and may be in contact with the rear pad PAD1.

In embodiments, a width of the top surface of the cell connection via CTV may be greater than a width at the bottom surface of the cell connection via CTV. In the direction from the top surface to the bottom surface of the cell connection via CTV, the width of the cell connection via CTV may gradually decrease.

In embodiments, as shown in FIG. 8, a plurality of cell connection vias CTV may be arranged to correspond to one landing pad wiring layer 132 or one rear pad PAD1. The plurality of cell connection vias CTV may commonly be electrically connected to one rear pad PAD1. However, disclosed concepts are not limited thereto. One cell connection via CTV may be arranged to correspond to one rear pad PAD1.

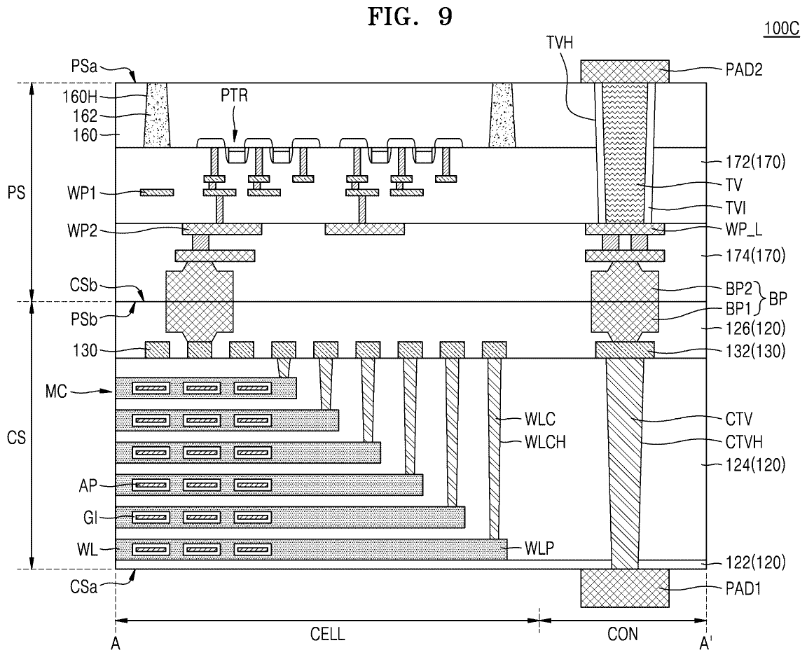

FIG. 9 is a cross-sectional view of a semiconductor device 100C according to embodiments.

Referring to FIG. 9, the semiconductor device 100C may have a structure in which a front surface (e.g., the second surface CSb) of the cell stack CS is bonded to a front surface (e.g., the second surface PSb) of the peripheral circuit stack PS. In embodiments, the bonding pad BP may be provided at an interface between the cell stack CS and the peripheral circuit stack PS. The cell stack CS may be attached to the peripheral circuit stack PS by a metal-oxide hybrid bonding method.

In embodiments, the via hole 160H may be arranged to penetrate the peripheral circuit substrate 160, and the via insulating layer 162 may be arranged in the via hole 160H. The via insulating layer 162 may function as an etch stopper in a grinding process to reduce the thickness of the peripheral circuit substrate 160. Thus, it may be possible for the peripheral circuit substrate 162 to be ground to a relatively small thickness.

In embodiments, a width of the top surface of the connection via TV may be greater than a width of the bottom surface of the connection via TV. In the direction from the top surface to the bottom surface of the connection via TV, the width of the connection via TV may gradually decrease.

In embodiments, some of the second wiring patterns WP2 may be referred to as landing pad wiring patterns WP_L. For example, the bottom surface of the connection via TV may be placed on the top surface of the landing pad wiring pattern WP_L and may be in contact with the top surface of the landing pad wiring patterns WP_L. In embodiments, in the process of removing a portion of the peripheral circuit substrate 160 and a portion of the first insulating layer 126 to form the connection via hole TVH extending in the vertical direction Z, the landing pad wiring pattern WP_L may be used as an etch stop layer.

In embodiments, the connection via TV may have a top surface arranged at the same level as the top surface of the peripheral circuit substrate 160. The bottom surface of the connection via TV may be arranged at the same level as the bottom surface of the first insulating layer 172.

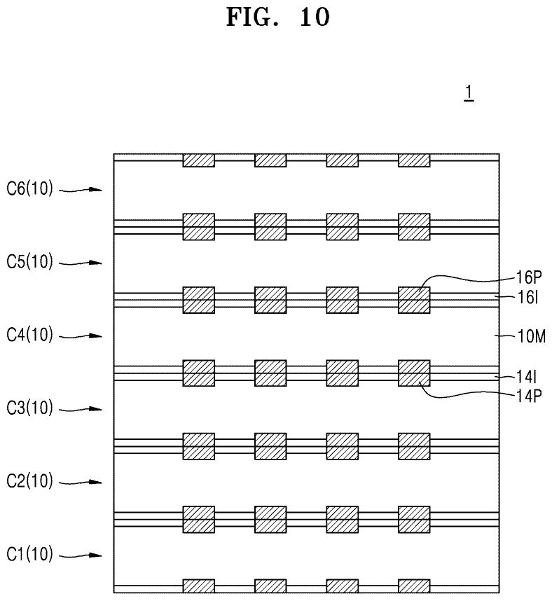

FIG. 10 is a schematic diagram of a semiconductor device 1 according to embodiments.

Referring to FIG. 10, the semiconductor device 1 may include a plurality of semiconductor dies 10 stacked in the vertical direction Z. The plurality of semiconductor dies 10 may be arranged at positions where the plurality of semiconductor dies 10 overlap one another in the vertical direction Z, and the plurality of the semiconductor dies 10 may be electrically connected to one another.

In embodiments, the plurality of semiconductor dies 10 may include a memory chip and may include, for example, a DRAM device. In embodiments, the plurality of semiconductor dies 10 may include a high bandwidth memory device. In embodiments, the plurality of semiconductor dies 10 may not be disposed on a buffer die, and the semiconductor device 1 may include a bufferless semiconductor device.

In embodiments, the plurality of semiconductor dies 10 may be attached to the buffer die, wherein the buffer die may include a logic chip. In embodiments, the plurality of semiconductor dies 10 may be attached to some areas of an interposer, and the logic chip may be mounted on other areas of the interposer.

In embodiments, the number of semiconductor dies 10 stacked in the vertical direction Z is not limited to the number shown in FIG. 10. For example, the number of semiconductor dies 10 may be from about 2 to about 5 or from about 7 to about 100. In embodiments, each semiconductor die 10 may include at least one of the semiconductor devices 100 (100A, 100B, and 100C) described with reference to FIGS. 1 to 9.

In embodiments, each of the plurality of semiconductor dies 10 may be attached or adhered to one another by a metal-oxide hybrid bonding method. In embodiments, a front pad 14P included in one semiconductor die 10 may be in contact with a rear pad 16P included in another semiconductor die 10 disposed directly on the one semiconductor die 10, and a front insulating layer 14I included in one semiconductor die 10 may be in contact with a rear insulating layer 16I included in another semiconductor die 10 disposed directly on the one semiconductor die 10.

In embodiments, the plurality of semiconductor dies 10 may include a first die C1, a second die C2, a third die C3, a fourth die C4, a fifth die C5, and a sixth die C6 stacked in the vertical direction Z. In embodiments, the front pad 14P included in the first die C1 may be in contact with the rear pad 16P included in the second die C2, and the front insulating layer 14I included in the first die C1 may be in contact with the rear insulating layer 16I included in the second die C2. In addition, the front pad 14P included in the second die C2 may be in contact with the rear pad 16P included in the third die C3, and the front insulating layer 14I included in the second die C2 may be in contact with the rear insulating layer 16I included in the third die C3. In this way, the plurality of semiconductor dies 10 may be stacked in the vertical direction Z by means of a metal-oxide hybrid bonding method.

In embodiments, the front pad 14P included in one semiconductor die 10 may correspond to the front pad PAD2 included in the semiconductor device 100 (100A, 100B, and 100C) described with reference to FIGS. 1 to 9, and the rear pad 16P included in one semiconductor die 10 may correspond to the rear pad PAD1 included in the semiconductor device 100 (100A, 100B, and 100C) described with reference to FIGS. 1 to 9. The front pad 14P and the rear pad 16P included in one semiconductor die 10 may be electrically connected to one another by the connection via TV and the cell connection via CTV included in the semiconductor devices 100 (100A, 100B, and 100C) described with reference to FIGS. 1 to 9.

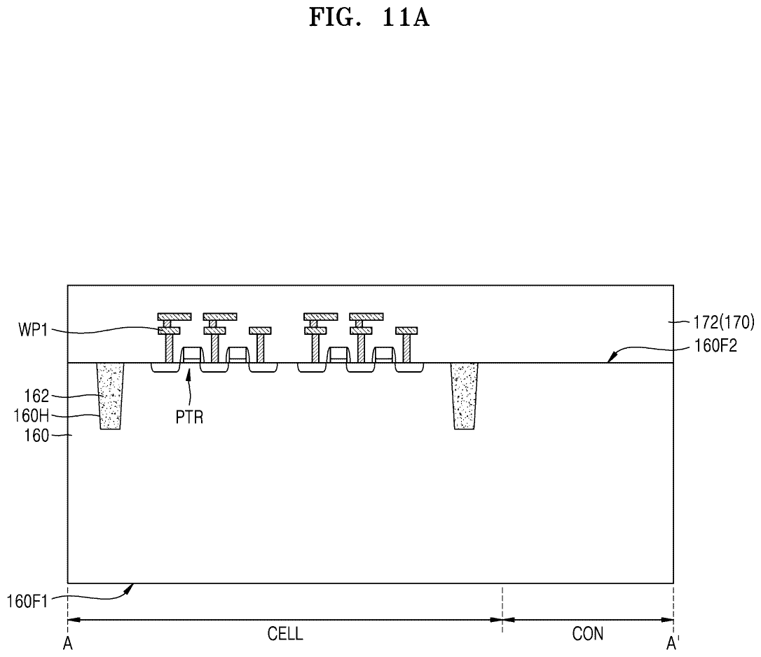

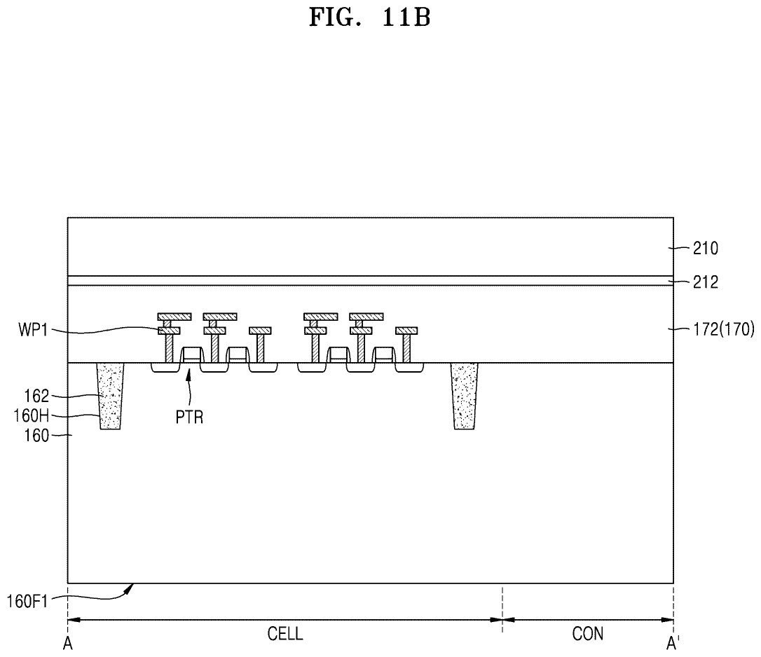

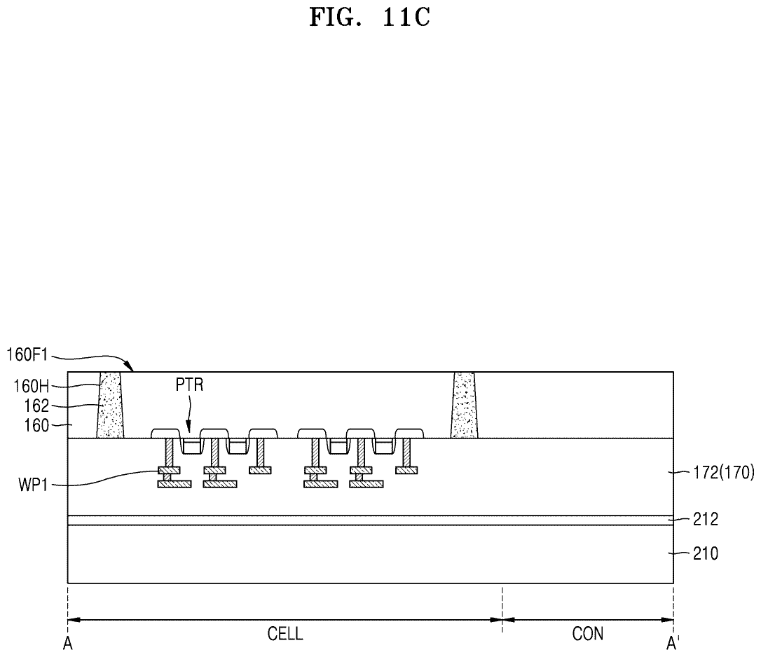

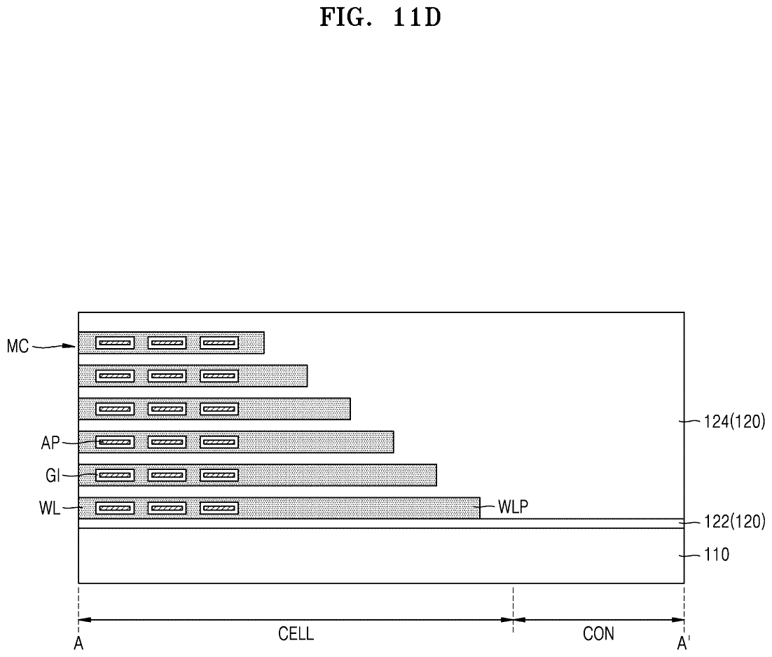

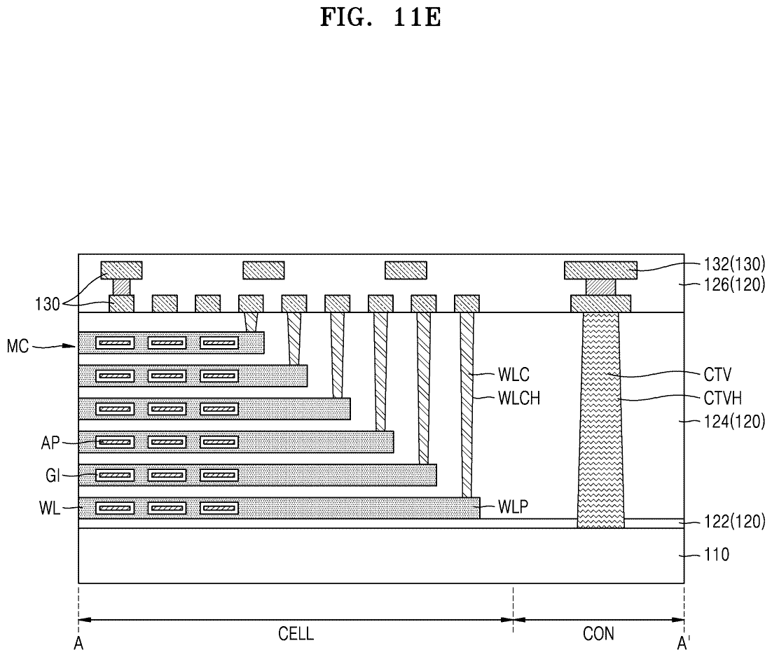

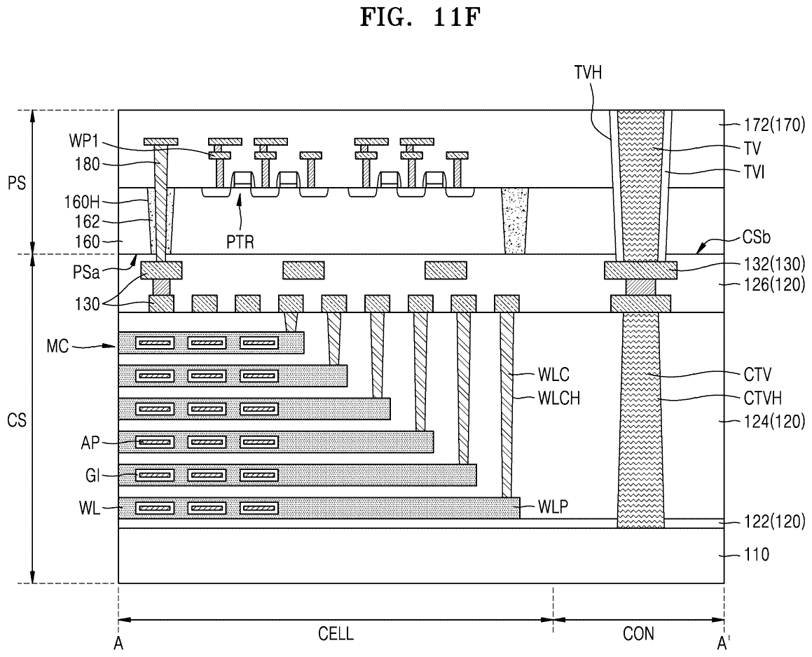

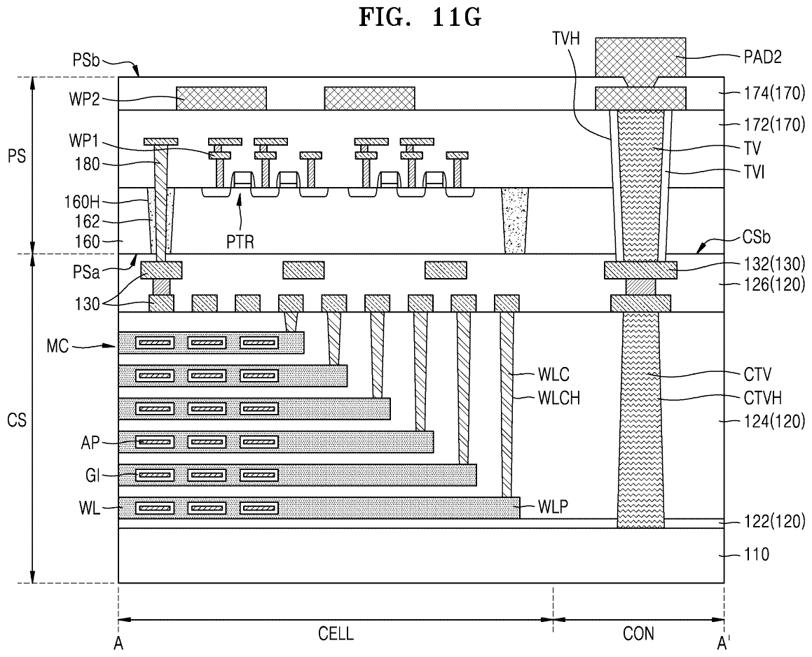

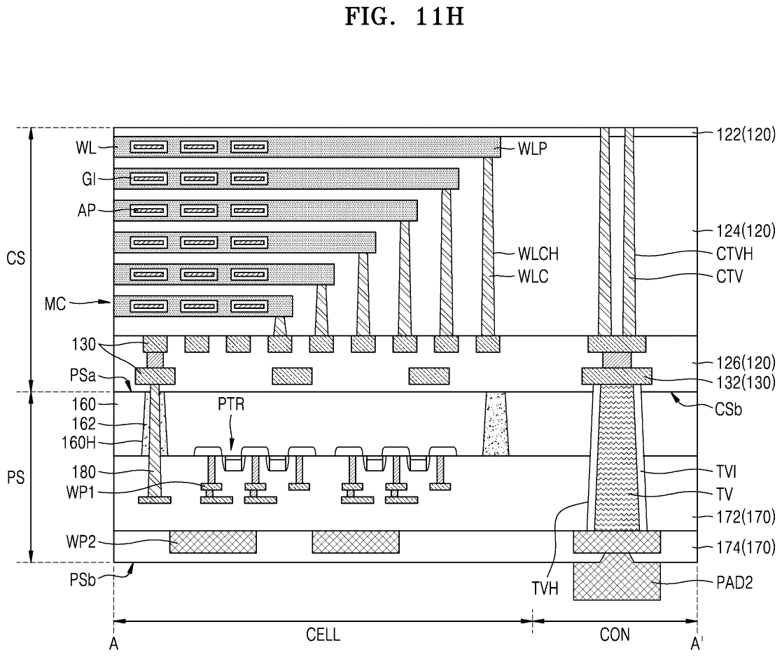

FIGS. 11A to 11H are schematic diagrams illustrating a method of manufacturing the semiconductor device 100, according to embodiments.

Referring to FIG. 11A, the peripheral circuit substrate 160 may be provided. The peripheral circuit substrate 160 may include a first surface 160F1 and a second surface 160F2. A mask pattern is formed on the second surface 160F2 of the peripheral circuit substrate 160, and a portion of the peripheral circuit substrate 160 is removed by using the mask pattern as an etching mask to form the via hole 160H. Thereafter, the via insulating layer 162 may be formed in the via hole 160H using an insulating material.

The peripheral circuit transistor PTR may be formed on the peripheral circuit substrate 160, and the first wiring pattern WP1 electrically connected to the peripheral circuit transistor PTR and the first insulating layer 172 covering the peripheral circuit transistor PTR may be formed. In embodiments, the first insulating layer 172 may include at least one of silicon oxide, silicon oxynitride, silicon nitride, or a low-k dielectric material.

In embodiments, the peripheral circuit transistor PTR may include at least one of a planar-type transistor, a finFET transistor, a multi-bridge channel transistor, or a buried channel array transistor.

Referring to FIG. 11B, a first carrier substrate 210 may be attached to the first insulating layer 172. In embodiments, an interface insulating layer 212 may be formed on the first carrier substrate 210, and the first carrier substrate 210 may be attached to the peripheral circuit substrate 160 such that the interface insulating layer 212 is in contact with the top surface of the first insulating layer 172.

In embodiments, the interface insulating layer 212 may include at least one of silicon oxide, silicon nitride, silicon oxynitride, and silicon carbon nitride.

In embodiments, the interface insulating layer 212 may be bonded to the first insulating layer 172 by an oxide bonding method. In embodiments, the plasma treatment may be performed on the surfaces of the interface insulating layer 212 and the first insulating layer 172. In embodiments, the surface treatment using a chemical substance may be performed on the surfaces of the interface insulating layer 212 and the first insulating layer 172. In embodiments, the high-temperature annealing treatment may be performed on the surfaces of the interface insulating layer 212 and the first insulating layer 172.

Referring to FIG. 11C, a structure where the first insulating layer 172 is attached to the first carrier substrate 210 may be inverted.

The grinding process for removing a portion of the peripheral circuit substrate 160 from the first surface 160F1 of the peripheral circuit substrate 160 may then be performed. The grinding process may be performed so that the top surface of the via insulating layer 162 is exposed. The grinding process may reduce the thickness of the peripheral circuit substrate 160 and may lower the level of the top surface of the peripheral circuit substrate 160.

In embodiments, the via insulating layer 162 may be used as an etch stop in the grinding process. For example, the grinding process may be performed so that the top surface of the via insulating layer 162 is exposed. The first surface 160F1 having a lowered level may be arranged on the same plane as the top surface of the via insulating layer 162.

Referring to FIG. 11D, the memory cell MC may be formed on a cell wafer 110.

In embodiments, a structure in which a plurality of memory cells MC are two-dimensionally disposed on the cell wafer 110 may be formed. For example, the plurality of memory cells MC may include the cell transistor CTR and the cell capacitor CAP (see FIGS. 4 and 5) arranged in the vertical direction Z. In embodiments, the plurality of semiconductor patterns AP may be spaced apart from one another in the vertical direction Z. The plurality of word lines WL may surround the plurality of semiconductor patterns AP and extend in the first horizontal direction X. The plurality of bit lines BL may be connected to first ends of the plurality of semiconductor patterns AP in the vertical direction Z. The plurality of cell capacitors CAP may be coupled to second ends opposite the first ends of the plurality of semiconductor patterns AP. The plurality of word lines WL may include a word line pad WLP varying in length in the second horizontal direction Y. The cover insulating layer 124 may cover the plurality of word lines WL and the word line pad WLP.

Referring to FIG. 11E, a mask pattern may be formed on the top surface of the cover insulating layer 124, and a portion of the cover insulating layer 124 may be removed to form the contact hole WLCH exposing the top surface of the word line pad WLP. Thereafter, the word line contact WLC may be formed in the contact hole WLCH by filling the contact hole WLCH with a conductive material.

In embodiments, in the process of forming the contact hole WLCH, a portion of the cover insulating layer 124 arranged in the connection region CON may be removed to form the via hole CTVH. The via hole CTVH may extend in the vertical direction Z through the cover insulating layer 124 and the bottom insulating layer 122, and the top surface of the cell wafer 110 may be exposed at the bottom of the via hole CTVH. In embodiments, in the process of forming the word line contact WLC in the contact hole WLCH, the cell connection via CTV may be formed in the via hole CTVH by filling the via hole CTVH with a conductive material.

In embodiments, the process of forming the cell connection via CTV may be performed before or after the word line contact WLC is formed.

In embodiments, in the etching process of the via hole CTVH, the top of the via hole CTVH may be exposed to the etching atmosphere for a longer time. Accordingly, the width of the top of the via hole CTVH may be formed to be greater than the width of the bottom of the via hole CTVH. In this case, the cell connection via CTV arranged in the via hole CTVH may be formed such that the width of the top surface or the first end of the cell connection via CTV arranged at the same level as the top surface of the cover insulating layer 124 is greater than the width of the bottom surface or the second end of the cell connection via CTV arranged at the same level as the bottom surface of the bottom insulating layer 122.

Thereafter, the upper wiring layer 130 may be formed on the cover insulating layer 124, and the upper insulating layer 126 covering the upper wiring layer 130 may be formed. In embodiments, the upper wiring layer 130 may be formed in a structure where two or more metal wiring layers having different vertical levels from one another are stacked, and the upper insulating layer 126 may be formed in a structure where a plurality of insulating layers are stacked to cover the two or more metal wiring layers.

A portion of the upper wiring layer 130 may be arranged at a position that vertically overlaps the cell connection via CTV and may be electrically connected to the cell connection via CTV. As such, the upper wiring layer 130 may be referred to as a landing pad wiring layer 132.

Referring to FIG. 11F, the cell wafer 110 may be bonded to the peripheral circuit substrate 160.

In embodiments, the peripheral circuit substrate 160 may be bonded to the cell wafer 110 such that the peripheral circuit substrate 160 is arranged at a higher vertical level than the memory cell MC disposed on the cell wafer 110.

In embodiments, the bottom surface of the peripheral circuit substrate 160 may be attached to the top surface of the upper insulating layer 126 such that the peripheral circuit substrate 160 is arranged at a higher vertical level than the cell wafer 110. In embodiments, the peripheral circuit substrate 160 may be bonded to the cell wafer 110 in such a manner that a bonding insulating layer is formed on the bottom surface of the peripheral circuit substrate 160, and the bonding insulating layer is bonded to the top surface of the upper insulating layer 126.

The through via contact 180 may then be further formed through the via insulating layer 162. The through via contact 180 may extend through the via insulating layer 162 into the cell stack CS and may be electrically connected to the upper wiring layer 130.

Then, a portion of the peripheral circuit substrate 160, a portion of the first insulating layer 172, and a portion of the upper insulating layer 126 may then be removed to form the connection via hole TVH. The top surface of the landing pad wiring layer 132 may be exposed at the bottom of the connection via hole TVH.

An insulating material may be conformally formed on the inner wall of the connection via hole TVH to form the connection via insulating layer TVI. The connection via insulating layer TVI may cover the entire sidewall of the connection via hole TVH. At least a portion of the top surface of the landing pad wiring layer 132 at the bottom of the connection via hole TVH may not be covered by the connection via insulating layer TVI. In embodiments, the connection via insulating layer TVI may be formed using silicon oxide, silicon nitride, or silicon oxynitride.

The metal material may then be used inside the connection via hole TVH to form the connection via TV. In embodiments, the connection via TV may be formed by an electrolytic plating process or an electroless plating process using copper or a copper alloy. In embodiments, a seed layer may be further formed on the inner wall of the connection via hole TVH by a sputtering process using copper, titanium, silver, platinum, or the like before forming the connection via TV.

In embodiments, in the etching process of the connection via hole TVH, the top of the connection via hole TVH may be exposed to the etching atmosphere for a longer time. Accordingly, the width of the top of the connection via hole TVH may be formed greater than the width of the bottom of the connection via hole TVH. In this case, the connection via TV arranged in the connection via hole TVH may be formed such that the width of the top surface or the first end of the connection via TV arranged at the same level as the top surface of the first insulating layer 172 is greater than the width of the bottom surface or the second end of the connection via TV arranged at a lower level than the bottom surface of the peripheral circuit substrate 160.

Referring to FIG. 11G, the second wiring pattern WP2 and the second insulating layer 174 may be formed on the top surfaces of the connection via TV and the first insulating layer 172. A portion of the second wiring pattern WP2 may be arranged at a position that vertically overlaps the connection via TV, and the second wiring pattern WP2 may be electrically connected to the connection via TV.

Then, the front pad PAD2 electrically connected to the second wiring pattern WP2 may be formed on the second insulating layer 174.

In embodiments, the front pad PAD2 may be formed by the electrolytic plating process or the electroless plating process using copper or a copper alloy. In embodiments, the seed layer may be further formed by the sputtering process using copper, titanium, silver, platinum, or the like before forming the front pad PAD2.

Referring to FIG. 11H, a structure in which the peripheral circuit stack PS is bonded to the cell stack CS may be inverted. The cell wafer 110 (see FIG. 11G) may then be removed to expose the bottom insulating layer 122. The end of the cell connection via CTV may also be exposed as the bottom insulating layer 122 is exposed.

Referring again to FIG. 2, the rear pad PAD1 may be formed on the bottom surface of the bottom insulating layer 122. In embodiments, the rear pad PAD1 may be formed by the electrolytic plating process or the electroless plating process using copper or a copper alloy. In embodiments, the seed layer may be further formed by the sputtering process using copper, titanium, silver, platinum, or the like before forming the rear pad PAD1.

The semiconductor device 100 may be completed by the above-described process.

In the method of manufacturing the semiconductor device 100 according to the embodiments, the peripheral circuit stack PS may be attached to the cell stack CS, then the connection via TV may be formed to pass through the peripheral circuit stack PS, and then the cell wafer 110 may be removed. The semiconductor device 100 may have a high degree of integration while having excellent electrical performance.

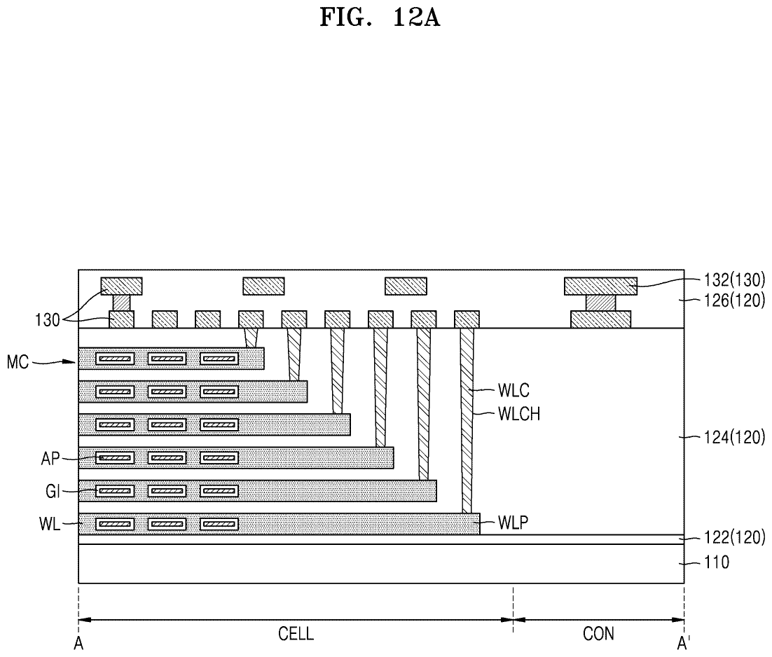

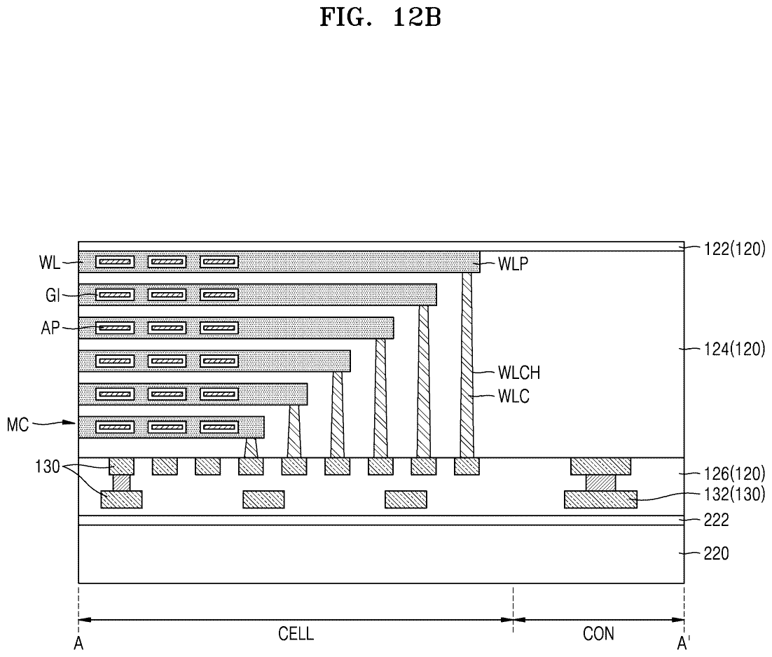

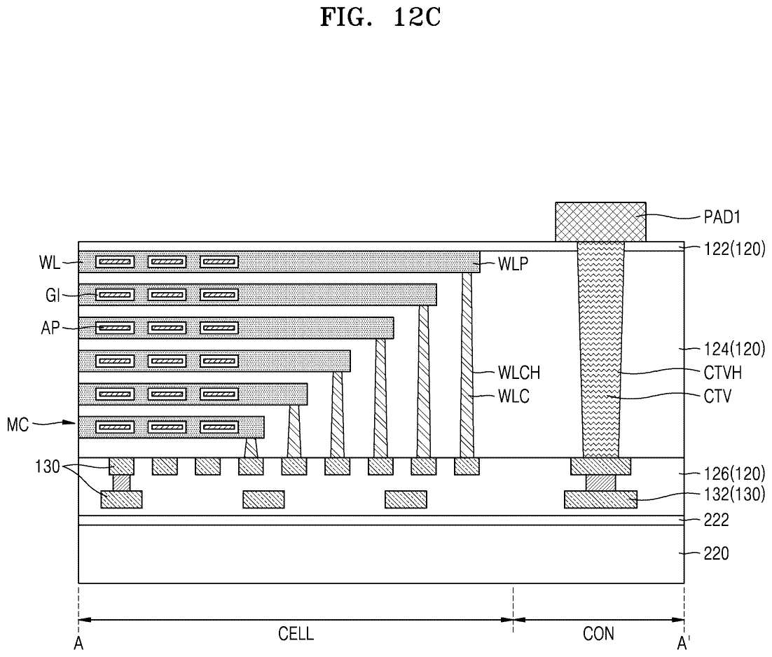

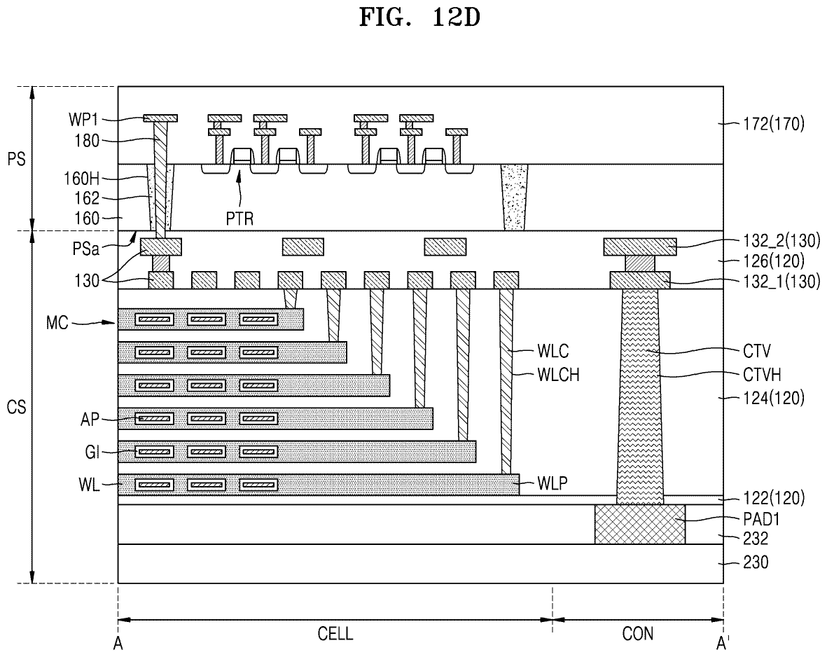

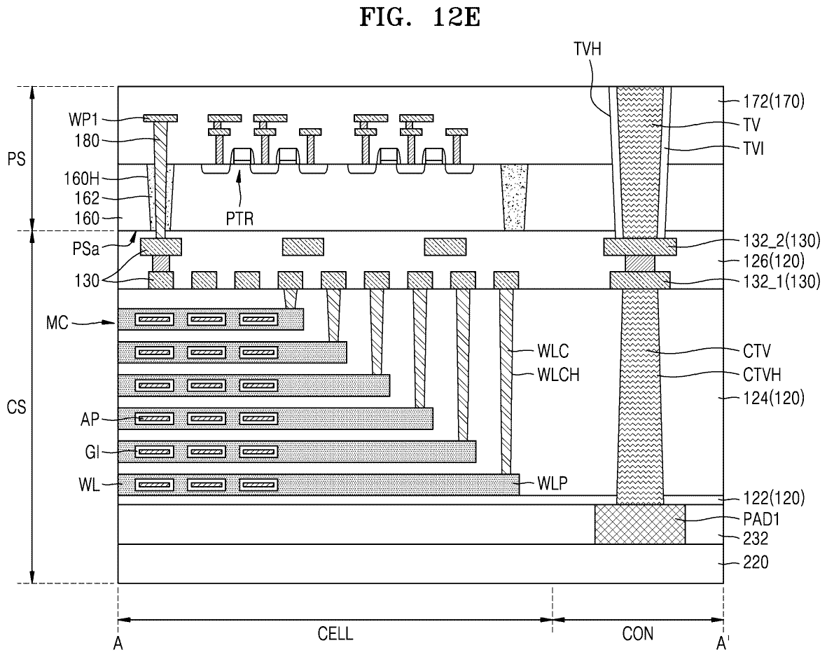

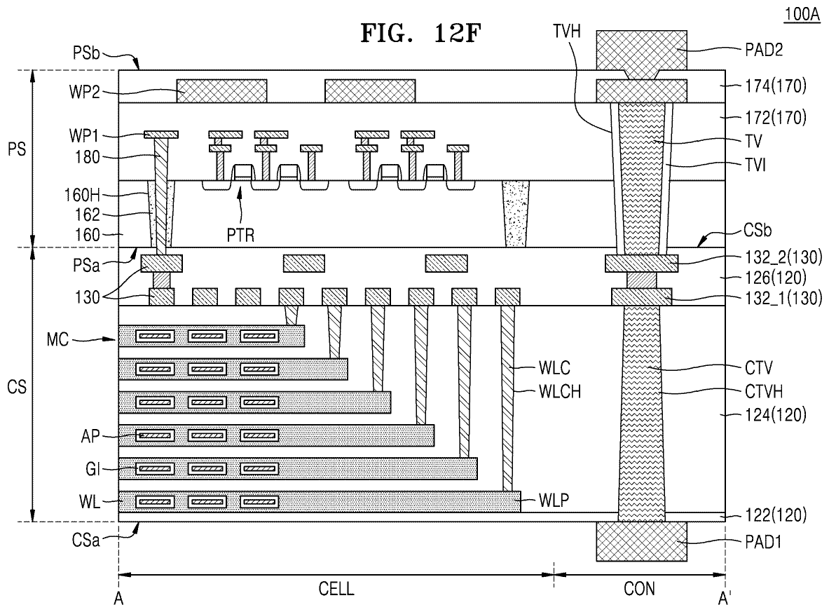

FIGS. 12A to 12F are schematic diagrams illustrating a method of manufacturing the semiconductor device 100A, according to embodiments.

Referring to FIG. 12A, the plurality of memory cells MC may be formed on the cell wafer 110 in a way that is similar to those described with reference to FIGS. 11D and 11E, and the word line contact WLC connected to the word line pad WLP of the plurality of memory cells MC may be formed.

The embodiment described with reference to FIG. 12A may be different from the method described with reference to FIGS. 11D and 11E in that the cell connection via CTV is not formed on the connection region CON.

Then, the upper wiring layer 130 may be formed, and the upper insulating layer 126 may be formed. In addition, the landing pad wiring layer 132 may be formed in the connection region CON in the process of forming the upper wiring layer 130.

Referring to FIG. 12B, the second carrier substrate 220 may be attached to the top surface of the upper insulating layer 126. In embodiments, the interface insulating layer 232 may be formed on the second carrier substrate 220, and the second carrier substrate 220 may be attached to the cell wafer 110 so that the interface insulating layer 232 is in contact with the top surface of the upper insulating layer 126.

The cell wafer 110 may then be removed to expose the top surface of the bottom insulating layer 122.

Referring to FIG. 12C, a mask pattern may be formed on the top surface of the bottom insulating layer 122, and the mask pattern may be used as an etching mask to remove a portion of the bottom insulating layer 122 and the cover insulating layer 124 arranged in the connection region CON to form the via hole CTVH. The via hole CTVH may extend in the vertical direction Z through the cover insulating layer 124 and the bottom insulating layer 122, and the top surface of the landing pad wiring layer 132 may be exposed at the bottom of the via hole CTVH.

Then, the cell connection via CTV may be formed in the via hole CTVH by filling the via hole CTVH with the conductive material.

In embodiments, the cell connection via CTV may be formed by the electrolytic plating process or the electroless plating process using copper or a copper alloy. In embodiments, the seed layer may be further formed on the inner wall of the via hole CTVH by the sputtering process using copper, titanium, silver, platinum, or the like before forming the cell connection via CTV.

In embodiments, the cell connection via CTV may be formed using at least one of a chemical vapor deposition process, a physical vapor deposition process, and an atomic layer deposition process, using tungsten, tungsten nitride, titanium, titanium nitride, ruthenium, cobalt, cobalt nitride, molybdenum, molybdenum nitride, or a combination thereof.

In embodiments, in the etching process of the via hole CTVH, the top of the via hole CTVH may be exposed to the etching atmosphere for a longer time. Accordingly, the width of the top of the via hole CTVH may be formed greater than the width of the bottom of the via hole CTVH. In this case, the cell connection via CTV arranged in the via hole CTVH may be formed such that the width of the top surface or the first end of the cell connection via CTV arranged at the same level as the top surface of the bottom insulating layer 122 is greater than the width of the bottom surface or the second end of the cell connection via CTV arranged at the same level as the bottom surface of the cover insulating layer 124.

Then, the rear pad PAD1 electrically connected to the cell connection via CTV may be formed on the top surface of the bottom insulating layer 122.

Referring to FIG. 12D, a third carrier substrate 230 may be attached to the top surface of the bottom insulating layer 122. In embodiments, an interface insulating layer 232 may be formed on the third carrier substrate 230, and the third carrier substrate 232 may be attached to the second carrier substrate 220 such that the interface insulating layer 232 is in contact with the top surface of the bottom insulating layer 122.

The structure where the third carrier substrate 230 is attached to the second carrier substrate 220 may be inverted. The second carrier substrate 220 and the interface insulating layer 232 may then be removed to expose the top surface of the upper insulating layer 126.

Then, the third carrier substrate 230 may be bonded to the peripheral circuit substrate 160.

In embodiments, the peripheral circuit substrate 160 may be bonded to the third carrier substrate 230 such that the peripheral circuit substrate 160 is arranged at a higher vertical level than the memory cell MC disposed on the third carrier substrate 230.

In embodiments, the bottom surface of the peripheral circuit substrate 160 may be attached to the top surface of the upper insulating layer 126 such that the peripheral circuit substrate 160 is arranged at a higher vertical level than the third carrier substrate 230. In embodiments, the peripheral circuit substrate 160 may be bonded to the upper insulating layer 126 in such a manner that the bonding insulating layer is formed on the bottom surface of the peripheral circuit substrate 166 and the bonding insulating layer is bonded to the top surface of the upper insulating layer 126.

The through via contact 180 may then be further formed through the via insulating layer 162. The through via contact 180 may extend through the via insulating layer 162 into the cell stack CS and may be electrically connected to the upper wiring layer 130.

Referring to FIG. 12E, a portion of the peripheral circuit substrate 160, a portion of the first insulating layer 172, and a portion of the upper insulating layer 126 may be removed to form the connection via hole TVH. The top surface of the landing pad wiring layer 132 may be exposed at the bottom of the connection via hole TVH.

The insulating material may be conformally formed on the inner wall of the connection via hole TVH to form the connection via insulating layer TVI. The metal material may then be used inside the connection via hole TVH to form the connection via TV.

In embodiments, in the etching process of the connection via hole TVH, the top of the connection via hole TVH may be exposed to the etching atmosphere for a longer time. Accordingly, the width of the top of the connection via hole TVH may be formed to be greater than the width of the bottom of the connection via hole TVH. In this case, the connection via TV arranged in the connection via hole TVH may be formed such that the width of the top surface or the first end of the connection via TV arranged at the same level as the top surface of the first insulating layer 172 is greater than the width of the bottom surface or the second end of the connection via TV arranged at a lower level than the bottom surface of the peripheral circuit substrate 160.

Referring to FIG. 12F, the second wiring pattern WP2 and the second insulating layer 174 may be formed on the top surfaces of the connection via TV and the first insulating layer 172. Then, the front pad PAD2 electrically connected to the second wiring pattern WP2 may be formed on the second insulating layer 174.

The semiconductor device 100A may be completed by the above-described process.

In the method of manufacturing the semiconductor device 100A according to the embodiments, the peripheral circuit stack PS may be attached to the cell stack CS, and then the connection via TV may be formed to pass through the peripheral circuit stack PS. The semiconductor device 100A may have a high degree of integration while having excellent electrical performance.

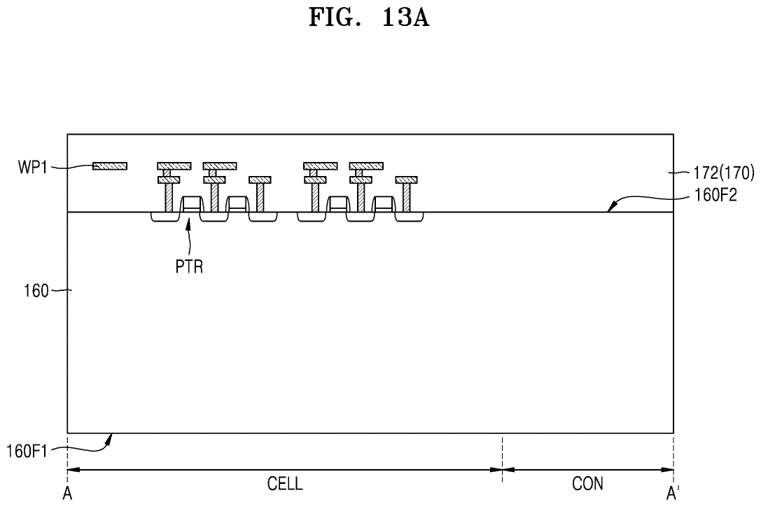

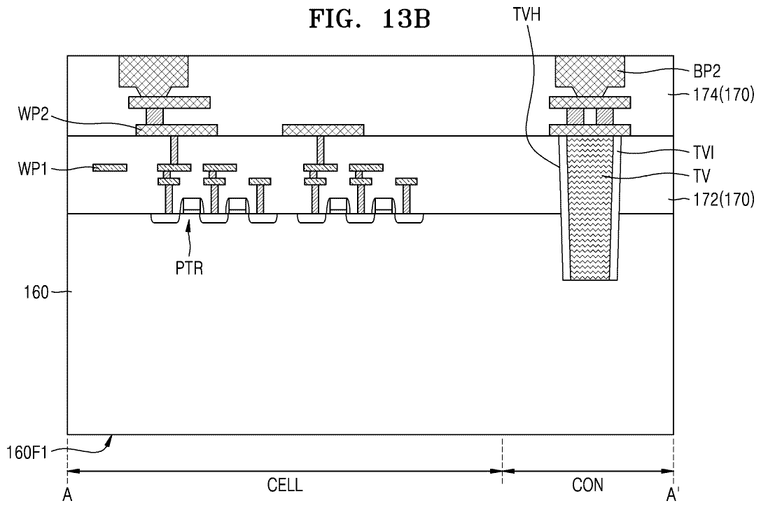

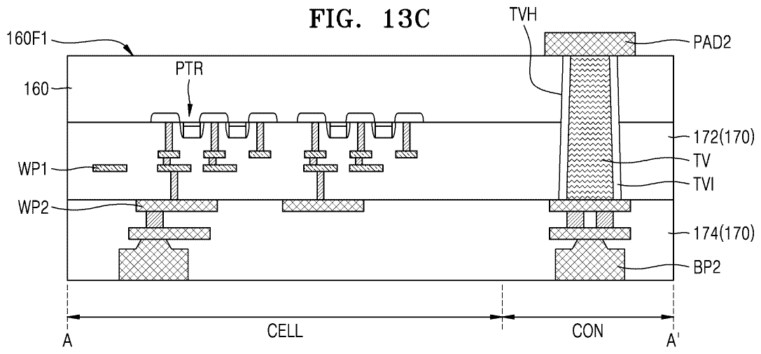

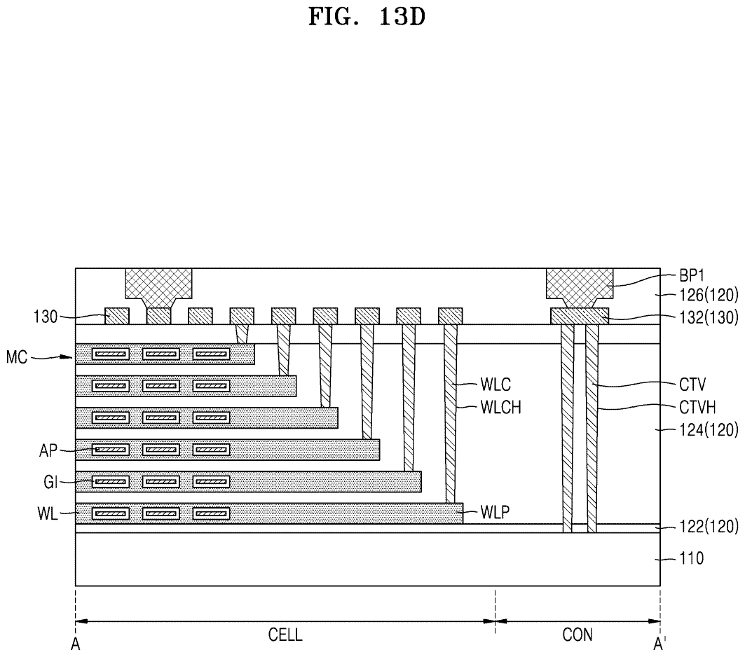

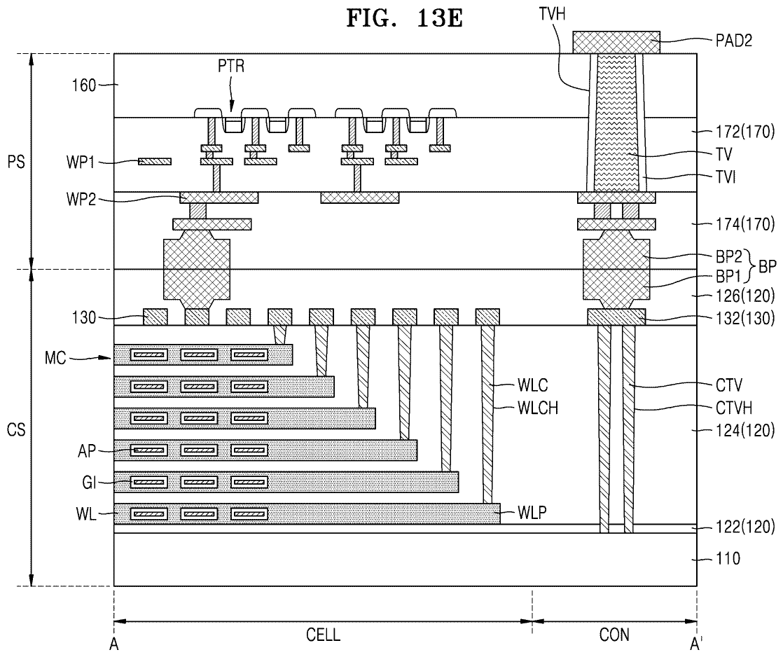

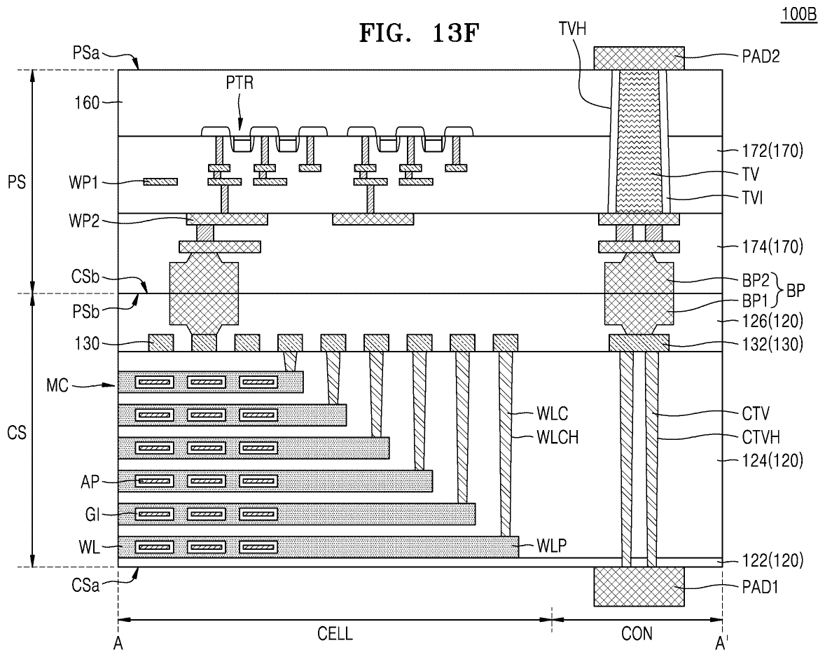

FIGS. 13A to 13F are schematic diagrams illustrating a method of manufacturing the semiconductor device 100B, according to embodiments.

Referring to FIG. 13A, the mask pattern is formed on the second surface 160F2 of the peripheral circuit substrate 160, and a portion of the peripheral circuit substrate 160 is removed by using the mask pattern as an etching mask to form the via hole 160H. The insulating material may then be used in the via hole 160H to form the via insulating layer 162.

Then, the peripheral circuit transistor PTR may be formed on the second surface 160F2 of the peripheral circuit substrate 160, and the first wiring pattern WP1 electrically connected to the peripheral circuit transistor PTR and the first insulating layer 172 covering the peripheral circuit transistor PTR may be formed.

Referring to FIG. 13B, a portion of the peripheral circuit substrate 160 and a portion of the first insulating layer 172 may be removed to form the connection via hole TVH. The connection via hole TVH may be formed at a vertical height that extends into the interior of the peripheral circuit substrate 160 and does not completely penetrate the peripheral circuit substrate 160.

The insulating material may then be conformally formed on the inner wall of the connection via hole TVH to form the connection via insulating layer TVI. The connection via insulating layer TVI may cover the entire sidewall of the connection via hole TVH. At least a portion of the top surface of the peripheral circuit substrate 160, at the bottom of the connection via hole TVH, may not be covered by the connection via insulating layer TVI. In embodiments, the connection via insulating layer TVI may be formed using silicon oxide, silicon nitride, or silicon oxynitride.

The metal material may then be used inside the connection via hole TVH to form the connection via TV. In embodiments, the connection via TV may be formed by the electrolytic plating process or the electroless plating process using copper or a copper alloy. In embodiments, the seed layer may be further formed on the inner wall of the connection via hole TVH by the sputtering process using copper, titanium, silver, platinum, or the like before forming the connection via TV.

In embodiments, in the etching process of the connection via hole TVH, the top of the connection via hole TVH may be exposed to the etching atmosphere for a longer time. Accordingly, the width of the top of the connection via hole TVH may be formed to be greater than the width of the bottom of the connection via hole TVH. In this case, the connection via TV arranged in the connection via hole TVH may be formed such that the width of the top surface or the first end of the connection via TV arranged at the same level as the top surface of the first insulating layer 172 is greater than the width of the bottom surface or the second end of the connection via TV arranged at a lower level than the top surface of the peripheral circuit substrate 160.

The second wiring pattern WP2 and the second insulating layer 174 may be formed on the top surfaces of the connection via TV and the first insulating layer 172. A portion of the second wiring pattern WP2 may be arranged at a position that vertically overlaps the connection via TV, and the second wiring pattern WP2 may be electrically connected to the connection via TV.

A portion of the second insulating layer 174 may then be removed to form a pad opening, and the second bonding pad BP2 may be formed in the pad opening.

In embodiments, the second bonding pad BP2 may be formed by the electrolytic plating process or the electroless plating process using copper or a copper alloy. In embodiments, the seed layer may be further formed on the inner wall of the pad opening by the sputtering process using copper, titanium, silver, platinum, or the like before forming the second bonding pad BP2.

In embodiments, the second bonding pad BP2 may have a top surface arranged on the same plane as the top surface of the second insulating layer 174.

Referring to FIG. 13C, a grinding process for flipping the peripheral circuit substrate 160 and removing a portion of the peripheral circuit substrate 160 from the first surface 160F1 of the peripheral circuit substrate 160 may be performed.

In embodiments, the grinding process may be performed so that the top surface or the second end of the connection via TV is exposed. Accordingly, the top surface or the second end of the connection via TV and the first surface 160F1 having a lowered level may be arranged in the same plane.

Referring to FIG. 13D, a process described with reference to FIGS. 11D and 11E may be performed to form the plurality of memory cells MC on the cell wafer 110, and the upper wiring layer 130 electrically connected to the plurality of memory cells MC and the upper insulating layer 126 covering the upper wiring layer 130 may be formed.

A portion of the upper insulating layer 126 may then be removed to form the pad opening, and the first bonding pad BP1 may be formed in the pad opening.

In embodiments, the first bonding pad BP1 may be formed by the electrolytic plating process or the electroless plating process using copper or a copper alloy. In embodiments, the seed layer may be further formed on the inner wall of the pad opening by the sputtering process using copper, titanium, silver, platinum, or the like before forming the first bonding pad BP1.

In embodiments, the first bonding pad BP1 may have a top surface disposed on the same plane as the top surface of the upper insulating layer 126.

Referring to FIG. 13E, the peripheral circuit substrate 160 may be bonded to the cell wafer 110. In embodiments, the peripheral circuit substrate 160 may be bonded onto the cell wafer 110 so that the top surface of the first bonding pad BP1 and the bottom surface of the second bonding pad BP2 are in contact with one another, and the top surface of the upper insulating layer 126 and the bottom surface of the second insulating layer 174 are in contact with one another.

Referring to FIG. 13F, the cell wafer 110 may be removed, and the rear pad PAD1 may be formed on the bottom surface of the bottom insulating layer 122.

The semiconductor device 100B may be completed by the above-described process.

In the method of manufacturing the semiconductor device 100B according to the embodiments, the peripheral circuit stack PS may be attached to the cell stack CS by the bonding pad BP in a front surface-to-front surface bonding structure. The semiconductor device 100B may have a high degree of integration while having excellent electrical performance.

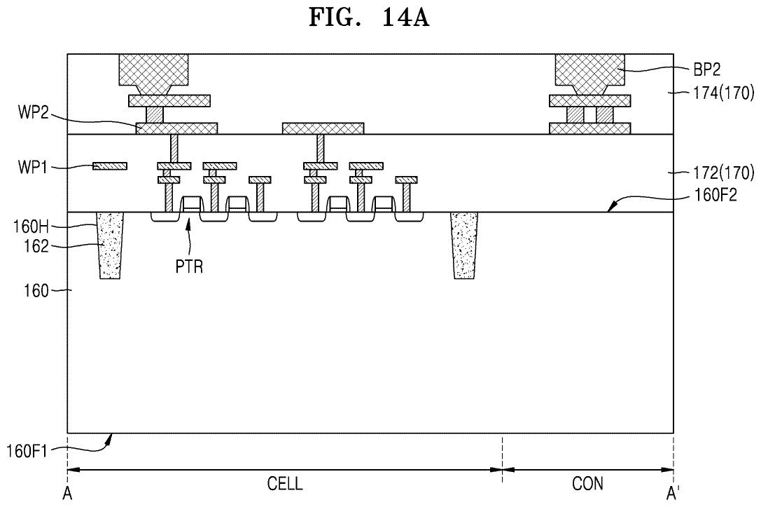

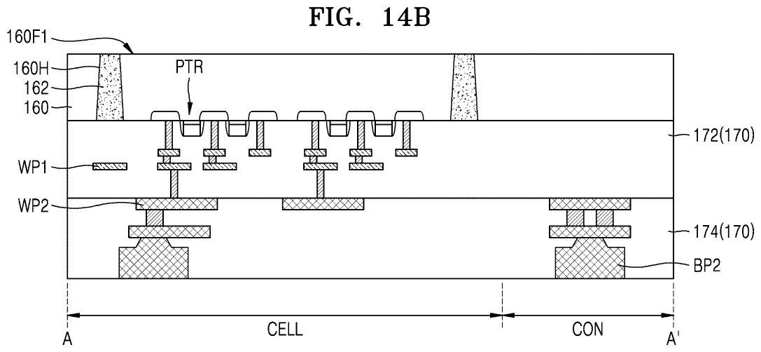

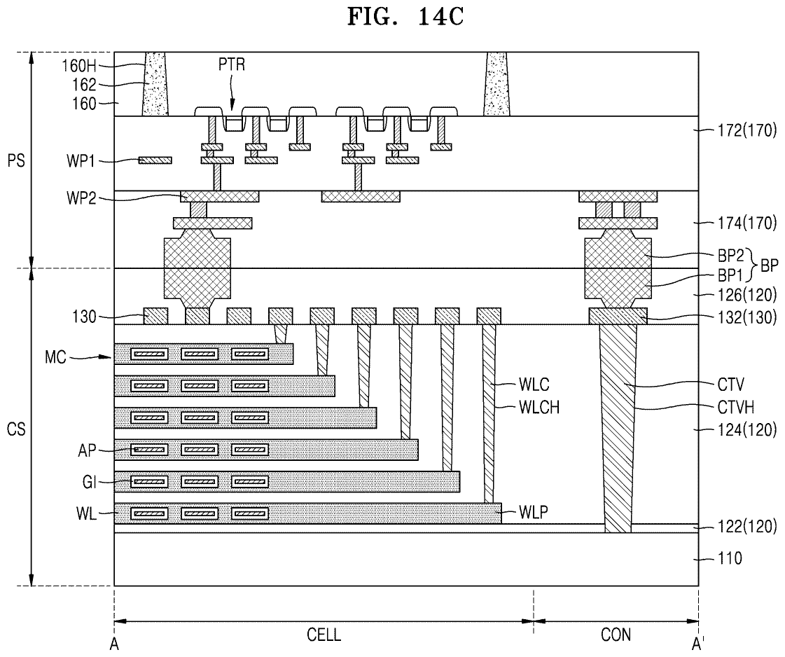

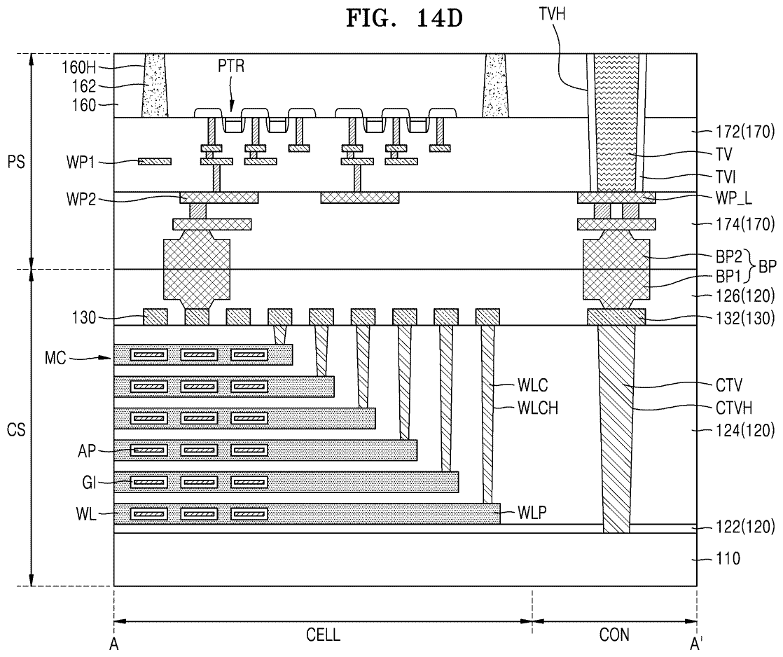

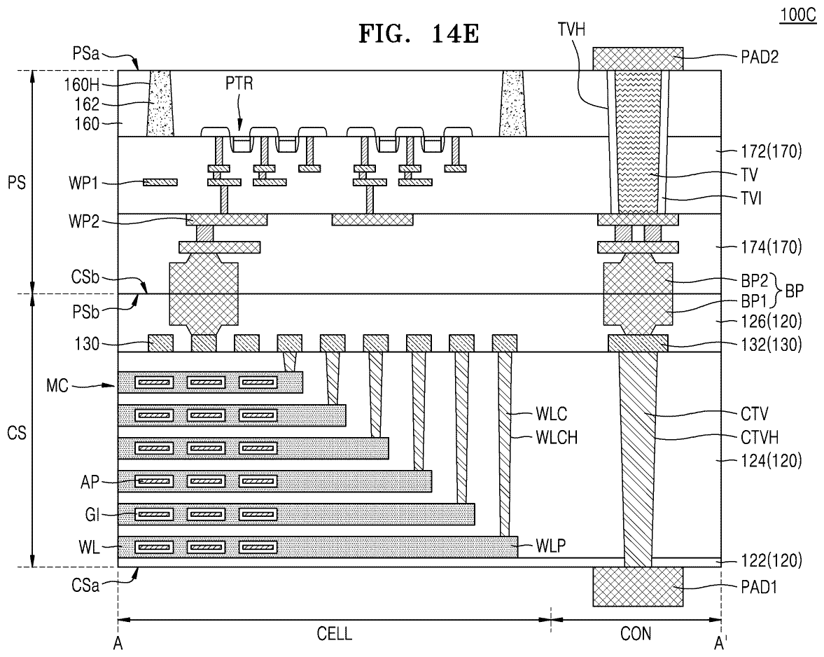

FIGS. 14A to 14E are schematic diagrams illustrating a method of manufacturing the semiconductor device 100C, according to embodiments.

Referring to FIG. 14A, the mask pattern is formed on the second surface 160F2 of the peripheral circuit substrate 160, and a portion of the peripheral circuit substrate 160 is removed by using the mask pattern as an etching mask to form the via hole 160H. The insulating material may then be used in the via hole 160H to form the via insulating layer 162.

Then, the peripheral circuit transistor PTR is formed on the second surface 160F2 of the peripheral circuit substrate 160, and the first wiring pattern WP1 electrically connected to the peripheral circuit transistor PTR and the first insulating layer 172 covering the peripheral circuit transistor PTR may be formed.

Then, the second wiring pattern WP2 and the second insulating layer 174 may be formed on the top surface of the first insulating layer 172. A portion of the second insulating layer 174 may be removed to form the pad opening, and the second bonding pad BP2 may be formed in the pad opening.

Referring to FIG. 14B, the grinding process for flipping the peripheral circuit substrate 160 and removing a portion of the peripheral circuit substrate 160 from the first surface 160F1 of the peripheral circuit substrate 160 may be performed.

In embodiments, the grinding process may be performed so that the top surface of the via insulating layer 162 is exposed. Accordingly, the top surface of the via insulating layer 162 and the first surface 160F1 having a lowered level may be arranged in the same plane.

Referring to FIG. 14C, the peripheral circuit substrate 160 may be bonded to the cell wafer 110. In embodiments, the peripheral circuit substrate 160 may be bonded onto the cell wafer 110 so that the top surface of the first bonding pad BP1 and the bottom surface of the second bonding pad BP2 are in contact with one another, and the top surface of the upper insulating layer 126 and the bottom surface of the second insulating layer 174 are in contact with one another.

Referring to FIG. 14D, a portion of the peripheral circuit substrate 160 and a portion of the first insulating layer 172 may be removed to form the connection via hole TVH. The connection via hole TVH may extend in the vertical direction Z through the peripheral circuit substrate 160 and the first insulating layer 172, and the top surface of the landing pad wiring pattern WP_L may be exposed at the bottom of the connection via hole TVH.

The insulating material may then be conformally formed on the inner wall of the connection via hole TVH to form the connection via insulating layer TVI. The connection via insulating layer TVI may cover the entire sidewall of the connection via hole TVH. At least a portion of the top surface of the landing pad wiring pattern WP_L at the bottom of the connection via hole TVH may not be covered by the connection via insulating layer TVI.

The metal material may then be used inside the connection via hole TVH to form the connection via TV. In embodiments, the connection via TV may be formed by the electrolytic plating process or the electroless plating process using copper or a copper alloy. In embodiments, the seed layer may be further formed on the inner wall of the connection via hole TVH by the sputtering process using copper, titanium, silver, platinum, or the like before forming the connection via TV.

In embodiments, in the etching process of the connection via hole TVH, the top of the connection via hole TVH may be exposed to the etching atmosphere for a longer time. Accordingly, the width of the top of the connection via hole TVH may be formed to be greater than the width of the bottom of the connection via hole TVH. In this case, the connection via TV arranged in the connection via hole TVH may be formed such that the width of the top surface or the first end of the connection via TV arranged at the same level as the top surface of the peripheral circuit substrate 160 is greater than the width of the bottom surface or the second end of the connection via TV arranged at a lower level than the bottom surface of the first insulating layer 172.

Referring to FIG. 14E, the front pad PAD2 electrically connected to the connection via TV may be formed on the top surface of the peripheral circuit substrate 160.

The cell wafer 110 may then be removed and the rear pad PAD1 electrically connected to the cell connection via CTV may be formed on the bottom surface of the exposed bottom insulating layer 122.

The semiconductor device 100C may be completed by the above-described process.

In the method of manufacturing the semiconductor device 100C according to the embodiments, the peripheral circuit stack PS is attached to the cell stack CS by the bonding pad BP in a front surface-to-front surface bonding structure, and then the connection via TV may be formed to pass through the peripheral circuit stack PS. The semiconductor device 100C may have a high degree of integration while having excellent electrical performance.

According to disclosed concepts, each semiconductor die includes a peripheral circuit stack and a cell stack including a three-dimensional semiconductor device and further includes a connection via extending through the peripheral circuit stack. The plurality of dies may be stacked in a vertical direction through a front pad and a rear pad. The semiconductor device may have a high degree of integration while having excellent electrical performance.

While disclosed concepts have been particularly shown and described with reference to embodiments thereof, it will be understood that various changes in form and details may be made therein without departing from the spirit and scope of the following claims.

What is claimed is:

1. A semiconductor device comprising:
a cell stack comprising a plurality of semiconductor patterns spaced apart from one another in a first horizontal direction and a vertical direction, a plurality of word lines surrounding the plurality of semiconductor patterns and extending in the first horizontal direction, a plurality of bit lines connected to a first end of each of the plurality of semiconductor patterns and extending in the vertical direction, and a plurality of cell capacitors connected to a second end of each of the plurality of semiconductor patterns and spaced apart from one another in the vertical direction;
a peripheral circuit stack disposed on the cell stack, the peripheral circuit stack comprising a peripheral circuit substrate disposed on a top surface of the cell stack, and a peripheral circuit transistor disposed on the peripheral circuit substrate;
a connection via extending in the vertical direction through the peripheral circuit substrate;
a front pad disposed on a top surface of the peripheral circuit stack and electrically connected to the connection via; and
a rear pad disposed on a bottom surface of the cell stack and electrically connected to the connection via.

2. The semiconductor device of claim 1, wherein the cell stack comprises an upper wiring layer electrically connected to the plurality of word lines or the plurality of cell capacitors, and an upper insulating layer covering the upper wiring layer, wherein the peripheral circuit stack is disposed on the upper insulating layer.

3. The semiconductor device of claim 2, wherein a bottom surface of the peripheral circuit substrate is in contact with a top surface of the upper insulating layer.

4. The semiconductor device of claim 2, wherein the upper wiring layer further comprises a landing pad wiring layer in contact with a bottom surface of the connection via.

5. The semiconductor device of claim 4, further comprising a connection via insulating layer arranged in a connection via hole passing through a portion of the peripheral circuit substrate and the upper insulating layer, and disposed on a sidewall of the connection via.

6. The semiconductor device of claim 5, wherein:
the connection via insulating layer is in contact with a top surface of the landing pad wiring layer, and
a portion of the connection via insulating layer is arranged between the connection via and the peripheral circuit substrate.

7. The semiconductor device of claim 4, wherein the cell stack further comprises a cover insulating layer covering the plurality of word lines and the plurality of cell capacitors, and a cell connection via extending in the vertical direction through the cover insulating layer, electrically connected to the landing pad wiring layer, and electrically connected to the rear pad.

8. The semiconductor device of claim 7, wherein:
the cell connection via is arranged at a position that vertically overlaps the landing pad wiring layer, and
the connection via is arranged at a position that vertically overlaps the landing pad wiring layer.

9. The semiconductor device of claim 7, wherein:
a width of a top surface of the connection via is greater than a width of a bottom surface of the connection via, and
a width of a top surface of the cell connection via is greater than a width of a bottom surface of the cell connection via.

10. The semiconductor device of claim 7, wherein:
a width of a top surface of the connection via is greater than a width of a bottom surface of the connection via, and
a width of a top surface of the cell connection via is less than a width of a bottom surface of the cell connection via.

11. The semiconductor device of claim 2, wherein the peripheral circuit stack further comprises a through via contact that penetrates the peripheral circuit substrate and is electrically connected to the upper wiring layer.

12. The semiconductor device of claim 11, wherein:
a width of a top surface of the connection via is greater than a width of a bottom surface of the connection via, and
a width of a top surface of the through via contact is greater than a width of a bottom surface of the through via contact.

13. The semiconductor device of claim 1, wherein the cell stack further comprises a bottom insulating layer disposed on a bottom surface of the plurality of word lines, wherein the rear pad is disposed on a bottom surface of the bottom insulating layer.

14. A semiconductor device comprising:
a cell stack comprising a plurality of semiconductor patterns spaced apart from one another in a first horizontal direction and a vertical direction, a plurality of word lines surrounding the plurality of semiconductor patterns and extending in the first horizontal direction, a plurality of bit lines connected to a first end of each of the plurality of semiconductor patterns and extending in the vertical direction, a plurality of cell capacitors connected to a second end of each of the plurality of semiconductor patterns and spaced apart from one another in the vertical direction, a cover insulating layer arranged to cover the plurality of word lines, and a bottom insulating layer disposed on a bottom surface of the plurality of word lines;
a peripheral circuit stack disposed on the cell stack, the peripheral circuit stack comprising a peripheral circuit substrate disposed on a top surface of the cell stack, and a peripheral circuit transistor disposed on the peripheral circuit substrate;
a connection via extending in the vertical direction through the peripheral circuit substrate;
a front pad disposed on a top surface of the peripheral circuit stack and electrically connected to the connection via; and
a rear pad disposed on a bottom surface of the cell stack, and disposed on a bottom surface of the bottom insulating layer and electrically connected to the connection via.

15. The semiconductor device of claim 14, wherein the cell stack comprises an upper wiring layer electrically connected to the plurality of word lines or the plurality of cell capacitors, and an upper insulating layer covering the upper wiring layer and disposed on a bottom surface of the peripheral circuit stack.

16. The semiconductor device of claim 14, wherein the cell stack further comprises a landing pad wiring layer in contact with a bottom surface of the connection via, and a connection via insulating layer arranged in a connection via hole penetrating a portion of the peripheral circuit substrate and the upper insulating layer and disposed on a sidewall of the connection via.

17. The semiconductor device of claim 16, wherein the cell stack further comprises a cell connection via extending in the vertical direction through the cover insulating layer, electrically connected to the landing pad wiring layer, and electrically connected to the rear pad.

18. The semiconductor device of claim 17, wherein:
a width of a top surface of the connection via is greater than a width of a bottom surface of the connection via, and
a width of a top surface of the cell connection via is greater than a width of a bottom surface of the cell connection via.

19. The semiconductor device of claim 17, wherein:
a width of a top surface of the connection via is greater than a width of a bottom surface of the connection via, and
a width of a top surface of the cell connection via is less than a width of a bottom surface of the cell connection via.

20. A semiconductor device comprising a plurality of dies stacked in a vertical direction, wherein each of the plurality of dies comprises:
a cell stack comprising a plurality of semiconductor patterns spaced apart from one another in a first horizontal direction and the vertical direction, a plurality of word lines surrounding the plurality of semiconductor patterns and extending in the first horizontal direction, a plurality of bit lines connected to a first end of each of the plurality of semiconductor patterns and extending in the vertical direction, a plurality of cell capacitors connected to a second end of each of the plurality of semiconductor patterns and spaced apart from one another in the vertical direction, a cover insulating layer arranged to cover the plurality of word lines, and a bottom insulating layer disposed on a bottom surface of the plurality of word lines;
a peripheral circuit stack disposed on the cell stack, the peripheral circuit stack comprising a peripheral circuit substrate disposed on a top surface of the cell stack, and a peripheral circuit transistor disposed on the peripheral circuit substrate;
a connection via extending in the vertical direction through the peripheral circuit substrate;
a front pad disposed on a top surface of the peripheral circuit stack and electrically connected to the connection via; and
a rear pad disposed on a bottom surface of the cell stack and electrically connected to the connection via.
